(19) United States
(12) Patent Application Publication
(10) Pub. No.: US 2025/0258521 A1
(43) Pub. Date: Aug. 14, 2025

(54) FOLDABLE SUBSTRATES, FOLDABLE ARTICLES, AND METHODS OF MAKING THE SAME

(71) Applicant: CORNING INCORPORATED, CORNING, NY (US)

(72) Inventors: Huayun Deng, Painted Post, NY (US); Timothy James Kiczenski, Corning, NY (US); Jeffrey Glenn Lynn, Wellsboro, PA (US); ChuanChe Wang, Horseheads, NY (US)

(21) Appl. No.: 19/041,536

(22) Filed: Jan. 30, 2025

Related U.S. Application Data
(60) Provisional application No. 63/552,268, filed on Feb. 12, 2024.

(51) Int. Cl. G06F 1/16; H05K 1/02; H05K 3/06

(52) U.S. Cl. CPC G06F 1/1652; H05K 1/0281; H05K 3/061; H05K 2201/2009; H05K 2203/013; H05K 2203/1163

(57) ABSTRACT

Foldable substrates have a first portion, a second portion, and a central portion positioned therebetween. The first portion and the second portion have a substrate thickness less than a central thickness of the central portion. A plurality of protrusions extend from a first central surface area of the central portion. A total protrusion area is a sum of an area of an upper surface of each protrusion of the plurality of protrusions. A total central area is an area of the central portion. An area ratio of the total protrusion area to the total central area is from 0.10 to 0.70. Methods include disposing a patterned mask on an initial major surface of a foldable substrate and then etching the foldable substrate to form the plurality of protrusions.

### CROSS-REFERENCE TO RELATED APPLICATIONS

This application claims the benefit of priority of U.S. Provisional Application Ser. No. 63/552,268, filed on Feb. 12, 2024, the content of which is relied upon and incorporated herein by reference in its entirety.

### FIELD

The present disclosure relates generally to foldable substrates, foldable articles, and methods of making the same and, more particularly, to foldable substrates comprising a plurality of protrusions, foldable substrates containing the same, and methods of making the same.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus that have low minimum bend radii and good impact and puncture resistance.

### SUMMARY

There are set forth herein foldable apparatus comprising foldable substrates, foldable substrates, and methods of making foldable apparatus and foldable substrates comprising foldable substrates that comprise a first portion, a second portion, and a central portion positioned therebetween. The foldable substrate can comprise glass-based and/or ceramic-based portions, which can provide good dimensional stability, reduced incidence of mechanical instabilities, good impact resistance, and/or good puncture resistance. The portions can comprise one or more compressive stress regions, which can further provide increased impact resistance and/or increased puncture resistance. By providing a foldable substrate comprising a glass-based and/or ceramic-based substrate, the foldable substrate can also provide increased impact resistance and/or puncture resistance while simultaneously facilitating good folding performance. In aspects, the substrate thickness can be sufficiently large (e.g., from about 50 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters (mm) or less, about 5 mm or less, or about 3 mm or less) based on the reduced thickness in the central portion, which can enable the foldability and/or rollability of the foldable substrate and/or foldable apparatus.

In aspects, the foldable apparatus and/or foldable substrates can comprise a recess, for example, a first central surface area recessed from a first major surface by a first distance. Providing a recess can form a central thickness that is less than a substrate thickness, which can facilitate folding of the foldable substrate and/or foldable apparatus. Further, providing the recess (e.g., with the plurality of protrusions) on only one side of the foldable substrate can provide a uniform opposite surface that can present a smooth, consistent surface for a user to interact with.

In aspects, the foldable apparatus and/or foldable substrates can comprise a recess, for example, a first central surface area recessed from a first major surface by a first distance. Providing a recess can provide a central thickness that is less than a substrate thickness, which can facilitate folding of the foldable substrate and/or foldable apparatus. Further, providing the recess (e.g., with the plurality of protrusions) on only one side of the foldable substrate can provide a uniform opposite surface that can present a smooth, consistent surface for a user to interact with.

The inventors of the present application have unexpectedly determined that providing a plurality of protrusions can improve impact resistance (e.g., as measured in the Quasi-Static Puncture Test) while allowing the foldable substrate and/or foldable substrate to still attain low parallel plate distances. Specifically, as discussed below with reference to FIG. 24, area ratios have unexpectedly been identified where the impact resistance (e.g., as measured in the Quasi-Static Puncture Test) is greater than a reference sample having a monolithic thickness with the same parallel plate distance (e.g., minimum parallel plate distance) (where the parallel plate distance and impact resistance of the reference sample is either directly measured experimentally or based on a calibration curve from a plurality of reference substrates), which demonstrates that the plurality of protrusion can increase impact resistance without negatively impacting foldability (e.g., parallel plate distance). Also, area ratios have unexpectedly been identified where the impact resistance (e.g., as measured in the Quasi-Static Puncture Test) is greater than a reference sample having a monolithic thickness equal to a weighted average thickness (defined below) (where the impact resistance of the reference sample is either directly measured experimentally or based on a calibration curve from a plurality of reference substrates), which demonstrates that the plurality of protrusion can increase impact resistance beyond what would be achieved for a substrate with the same weighted average thickness. Being above the calibration curve corresponds to an improvement in impact resistance beyond what would be expected (or obtained) for a monolithic substrate with a minimum parallel plate distance equal to that of the foldable substrate. For example, providing an area ratio from 0.10 to 0.70 (e.g., from 0.20 to 0.60, or from 0.25 to 0.50) can unexpectedly provide improved impact resistance (e.g., as measured in the Quasi-Static Puncture Test), for example, relative to a reference substrate with the same parallel plate distance or with the same weighted average thickness. Also, providing a plurality of protrusions arranged such that there is not a protrusion of the plurality of protrusions impinged by the midline (e.g., fold plane 109) can decrease a bend-induced stress on the foldable substrate.

Providing rounded corners for the cross-sectional shape of a protrusion of the plurality of protrusions can decrease stress concentrations at the corners of the protrusions, which can decrease a maximum bending stress associated with folding to a predetermined parallel plate distance and/or increase a reliability of folding the foldable substrate and/or foldable apparatus. Also, providing a plurality of protrusions (e.g., comprising substantially the substrate thickness) can increase a puncture resistance of the central region (e.g., due to the increased thickness of the plurality of protrusions relative to the first central surface area) while the central region (excluding the plurality of protrusions) can still facilitate folding of the foldable apparatus and/or foldable substrate. In further aspects, providing a plurality of substantially constant local thicknesses (e.g., substantially equal to the central thickness) between corresponding adjacent pairs of protrusions of the plurality of protrusions can simplify manufacturing, for example, enabling the local thickness between an adjacent pair of protrusions to be formed in a single etching step (e.g., with the portions corresponding to the adjacent pair of protrusions being masked).

Some example aspects of the disclosure are described below with the understanding that any of the features of the various aspects may be used alone or in combination with one another.

Aspect 1. A foldable substrate comprising:
a substrate thickness defined between a first major surface and a second major surface opposite the first major surface in a thickness direction;
a first portion comprising the substrate thickness;
a second portion comprising the substrate thickness;
a central portion positioned between the first portion and the second portion, the central portion comprising a first central surface area and a second central surface area opposite the first central surface area, a central thickness defined between the first central surface area and the second central surface area in the thickness direction the central thickness is less than the substrate thickness; and
a plurality of protrusions extending from the first central surface area by at least 5 micrometers, each protrusion comprising an upper surface within 5 micrometers in the thickness direction from a point corresponding to a maximum height of the corresponding protrusion from the first central surface area;
a total protrusion area is a sum of an area of the upper surface of each protrusion of the plurality of protrusions, a total central area is an area of the central portion in a plane perpendicular to the thickness direction and impinging the first central surface area,
wherein the foldable substrate comprises a glass-based material or a ceramic-based material, and an area ratio of the total protrusion area to the total central area is from 0.10 to 0.70.

Aspect 2. The foldable substrate of aspect 1, wherein the area ratio of the total protrusion area to the total central area is from 0.20 to 0.60.

Aspect 3. The foldable substrate of any one of aspects 1-2, wherein the area ratio of the total protrusion area to the total central area is from 0.25 to 0.50.

Aspect 4. The foldable substrate of any one of aspects 1-3, wherein the plurality of protrusions extend from the first central surface area by at least 10 micrometers.

Aspect 5. The foldable substrate of any one of aspects 1-4, wherein the foldable substrate achieves a minimum parallel plate distance in a Parallel Plate Test from 1 millimeter to 6 millimeters.

Aspect 6. The foldable substrate of any one of aspects 1-4, wherein the foldable substrate achieves a parallel plate distance in a Parallel Plate Test of 5 millimeters or less.

Aspect 7. The foldable substrate of any one of aspects 1-4, wherein the foldable substrate achieves a minimum parallel plate distance in a Parallel Plate Test, a reference substrate comprises a monolithic thickness and achieves a reference minimum parallel plate distance in the Parallel Plate Test substantially equal to the minimum parallel plate distance of the foldable substrate, and a puncture resistance of the foldable substrate measured in a Quasi-Static Puncture Test is greater than a reference puncture resistance of the reference substrate measured in the Quasi-Static Puncture Test.

Aspect 8. The foldable substrate of any one of aspects 1-4, wherein the foldable substrate achieves a minimum parallel plate distance in a Parallel Plate Test and exhibits a puncture resistance measured in a Quasi-Static Puncture Test, the puncture resistance is greater than a predicted puncture resistance for the minimum parallel plate distance based on a calibration curve from a plurality of reference substrates comprising the same material as the foldable substrate and monolithic thicknesses including values of the monolithic thicknesses that achieve corresponding minimum parallel plate distances greater than the minimum parallel plate distance of the foldable substrate and less than the minimum parallel plate distance of the foldable substrate.

Aspect 9. The foldable substrate of any one of aspects 1-6 or 8 inclusive, wherein the foldable substrate exhibits a puncture resistance measured in a Quasi-Static Puncture Test, a weighted average thickness TWA of the central portion defined as TWA=(1−AR)*TC+AR*TP, wherein AR is the area ratio, TC is the central thickness, and TP is a combined protrusion thickness defined between the second central surface area of the central portion and the upper surface of a protrusion of the plurality of protrusions, and the puncture resistance is greater than a reference puncture resistance of a reference substrate comprising a uniform thickness equal to the weighted average thickness and the same material as the foldable substrate.

Aspect 10. The foldable substrate of any one of aspects 1-7, wherein the foldable substrate exhibits a puncture resistance measured in a Quasi-Static Puncture Test, a weighted average thickness TWA of the central portion defined as TWA=(1−AR)*TC+AR*TP, wherein AR is the area ratio, TC is the central thickness, and TP is a combined protrusion thickness defined between the second central surface area of the central portion and the upper surface of a protrusion of the plurality of protrusions, and the puncture resistance is greater than a predicted puncture resistance for the weighted average thickness based on a calibration curve from a plurality of reference substrates comprising the same material as the foldable substrate and monolithic thicknesses including values of the monolithic thicknesses greater than the weighted average thickness and less than the weighted average thickness.

Aspect 11. The foldable substrate of any one of aspect 1-8, wherein a combined thickness between the second central surface area of the central portion and the upper surface of the protrusion is less than or equal to the substrate thickness.

Aspect 12. The foldable substrate of any one of aspect 1-8, wherein the first major surface extends along a first plane, a first distance is defined between the first plane and the first central surface area in the thickness direction, a protrusion height defined between the first central surface area and the upper surface of a protrusion of the plurality of protrusions in the thickness direction, and the first distance is greater than or equal to the protrusion height.

Aspect 13. The foldable substrate of aspect 12, wherein a ratio of the protrusion height to the first distance is from 0.30 to 1.0.

Aspect 14. The foldable substrate of aspect 12, wherein the first distance is substantially equal to the protrusion height.

Aspect 15. The foldable substrate of any one of aspect 9-14, wherein a width of the upper surface of a protrusion of the plurality of protrusions in a direction between the first portion and the second portion is from 20 micrometers to 1 millimeter.

Aspect 16. The foldable substrate of aspect 15, wherein the protrusion width is from 80 micrometers to 310 micrometers.

Aspect 17. The foldable substrate of any one of aspect 1-16, wherein the plurality of protrusions are aligned in a row extending in a first direction between the first portion and the second portion.

Aspect 18. The foldable substrate of aspect 17, wherein the foldable substrate comprises a substrate width measured in a width direction perpendicular to the thickness direction and the first direction, a protrusion of the plurality of protrusions extends for a distance in the width direction that is from 50% of the substrate width to 100% of the substrate width.

Aspect 19. The foldable substrate of aspect 17, wherein the plurality of protrusions are arranged in a two-dimensional array including the row extending between the first portion and the second portion, and at least three protrusions of the plurality of protrusions in a column of a plurality of columns extending perpendicular to the row.

Aspect 20. The foldable substrate of aspect 19, wherein protrusions of the plurality of protrusions in a first column of the plurality of columns is aligned with corresponding protrusions of a second column of the plurality of columns, where the first column is adjacent to the second column.

Aspect 21. The foldable substrate of aspect 19, wherein protrusions of the plurality of protrusions in a first column of the plurality of columns is offset from corresponding protrusions of a second column of the plurality of columns, where the first column is adjacent to the second column.

Aspect 22. The foldable substrate of any one of aspects 16-21, wherein a gap width between adjacent protrusions in the row in the first direction is from 150 micrometers to 1 millimeter.

Aspect 23. The foldable substrate of aspect 22, wherein the gap width is from 200 micrometers to 500 micrometers.

Aspect 24. The foldable substrate of any one of aspects 1-23, wherein the second major surface comprises the second central surface area.

Aspect 25. The foldable substrate of any one of aspects 1-23, wherein the second major surface is flush with the second central surface area.

Aspect 26. The foldable substrate of any one of aspects 1-25, further comprising:
a first compressive stress region extending to a first depth of compression from the first major surface in the first portion;
a second compressive stress region extending to a second depth of compression from the second major surface in the first portion;
a third compressive stress region extending to a third depth of compression from the first major surface in the second portion; and
a fourth compressive stress region extending to a fourth depth of compression from the second major surface in the second portion.

Aspect 27. The foldable substrate of aspect 26, further comprising:
a first central compressive stress region extending to a first central depth of compression from the first central surface area; and
a second central compressive stress region extending to a second central depth of compression from the second central surface area.

Aspect 28. The foldable substrate of any one of aspects 26-27, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, and the fourth compressive stress region comprises a fourth maximum compressive stress.

Aspect 29. The foldable substrate of aspect 28, wherein the second maximum compressive stress is about 400 MegaPascals or more, and the fourth maximum compressive stress is about 400 MegaPascals or more.

Aspect 30. The foldable substrate of any one of aspects 1-29, wherein the substrate thickness is in a range from about 50 micrometers to about 5 millimeters.

Aspect 31. The foldable substrate of any one of aspects 1-29, wherein the substrate thickness is in a range from about 100 micrometers to about 200 micrometers.

Aspect 32. The foldable substrate of any one of aspects 1-31, wherein the central thickness in a range from about 25 micrometers to about 120 micrometers.

Aspect 33. The foldable substrate of any one of aspects 1-31, wherein the central thickness is in a range from about 25 micrometers to about 80 micrometers.

Aspect 34. The foldable substrate of any one of aspects 1-33, wherein the foldable substrate comprises a glass-based substrate.

Aspect 35. The foldable substrate of any one of aspects 1-33, wherein the foldable substrate comprises a ceramic-based substrate.

Aspect 36. A foldable apparatus comprising:
the foldable substrate of any one of aspects 1-35; and
a polymer-based portion positioned at least between an adjacent pair of protrusions of the plurality of protrusions,
wherein a magnitude of a difference between an index of refraction of the foldable substrate and an index of refraction of the polymer-based portion is about 0.1 or less.

Aspect 37. A consumer electronic product, comprising:
a housing comprising a front surface, a back surface, and a side surface;
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the foldable substrate of any one of aspects 1-35.

Aspect 38. A method of making a foldable substrate comprising:
disposing a patterned mask on a central portion of an initial major surface of an initial substrate, the patterned mask comprising a plurality of separate sections; and
etching the initial major surface of the initial substrate to form a central portion of the foldable substrate with a plurality of protrusions extending from a first central surface area by at least 5 micrometers, and the plurality of protrusions corresponding to the plurality of separate sections of the patterned mask on central portion of the initial major surface,
wherein each protrusion of the plurality of protrusions comprising an upper surface within 5 micrometers in the thickness direction from a point corresponding to a maximum height of the corresponding protrusion from the first central surface area,
a total protrusion area is a sum of sum of an area of the upper surface of each protrusion of the plurality of protrusions, a total central area is an area of the central portion in the plane perpendicular to the thickness direction and impinging the first central surface area, the foldable substrate comprises a glass-based material or a ceramic-based material, and an area ratio of the total protrusion area to the total central area is from 0.10 to 0.70.

Aspect 39. The method of aspect 38, wherein the area ratio of the total protrusion area to the total central area is from 0.20 to 0.60.

Aspect 40. The method of any one of aspects 38-39, wherein the area ratio of the total protrusion area to the total central area is from 0.25 to 0.50.

Aspect 41. The method of any one of aspects 38-40, wherein the plurality of protrusions extend from the first central surface area by at least 10 micrometers.

Aspect 42. The method of any one of aspects 38-41, wherein the disposing the patterned mask comprises ink-jet printing the patterned mask.

Aspect 43. The method of any one of aspects 38-42, wherein, before etching the initial major surface, the method comprises disposing a first mask over a first portion of the initial major surface and a second mask of a second portion of the initial major surface, the central portion positioned between the first portion and the second portion.

Aspect 44. The method of any one of aspects 38-42, wherein, before etching the initial major surface, the method comprises disposing a third mask over an opposing major surface of the initial substrate opposite the initial major surface.

Aspect 45. The method of any one of aspects 38-44, a section of the plurality of sections comprises a width from 50 micrometers to 1 millimeter.

Aspect 46. The method of any one of aspects 38-45, wherein the plurality of sections are aligned in a row extending in a first direction.

Aspect 47. The method of aspect 46, wherein the plurality of sections are arranged in a two-dimensional array including the row, and at least three sections of the plurality of sections are in a column of a plurality of columns extending perpendicular to the row.

Aspect 48. The method substrate of aspect 47, wherein sections of the plurality of sections in a first column of the plurality of columns is aligned with corresponding sections of a second column of the plurality of columns, where the first column is adjacent to the second column.

Aspect 49. The method of aspect 47, wherein sections of the plurality of sections in a first column of the plurality of columns is offset from corresponding section of a second column of the plurality of columns, where the first column is adjacent to the second column.

Aspect 50. The method of any one of aspects 46-49, wherein a gap between adjacent sections in the row in the first direction is from 150 micrometers to 1 millimeter.

Aspect 51. The method of any one of aspects 38-50, wherein the foldable substrate comprises:
a substrate thickness defined between the first major surface and a second major surface opposite the first major surface in a thickness direction;
a first portion comprising the substrate thickness;
a second portion comprising the substrate thickness; and
a central portion positioned between the first portion and the second portion, the central portion comprising the first central surface area and a second central surface area opposite the first central surface area, a central thickness defined between the first central surface area and the second central surface area in the thickness direction the central thickness is less than the substrate thickness.

Aspect 52. The method of aspect 51, wherein the foldable substrate achieves a minimum parallel plate distance in a Parallel Plate Test from 1 millimeter to 6 millimeters.

Aspect 53. The method of aspect 51, wherein the foldable substrate achieves a parallel plate distance in a Parallel Plate Test of 5 millimeters or less.

Aspect 54. The method of aspect 51, wherein the foldable substrate achieves a minimum parallel plate distance in a Parallel Plate Test, a reference substrate comprises a monolithic thickness and achieves a reference minimum parallel plate distance in the Parallel Plate Test substantially equal to the minimum parallel plate distance of the foldable substrate, and a puncture resistance of the foldable substrate measured in a Quasi-Static Puncture Test is greater than a reference puncture resistance of the reference substrate measured in the Quasi-Static Puncture Test.

Aspect 55. The method of aspect 51, wherein the foldable substrate achieves a minimum parallel plate distance in a Parallel Plate Test and exhibits a puncture resistance measured in a Quasi-Static Puncture Test, the puncture resistance is greater than a predicted puncture resistance for the minimum parallel plate distance based on a calibration curve from a plurality of reference substrates comprising the same material as the foldable substrate and monolithic thicknesses including values of the monolithic thicknesses that achieve corresponding minimum parallel plate distances greater than the minimum parallel plate distance of the foldable substrate and less than the minimum parallel plate distance of the foldable substrate.

Aspect 56. The method of aspects 51-53 or 55 inclusive, wherein the foldable substrate exhibits a puncture resistance measured in a Quasi-Static Puncture Test, a weighted average thickness TWA of the central portion defined as TWA=(1−AR)*TC+AR*TP, wherein AR is the area ratio, TC is the central thickness, and TP is a combined protrusion thickness defined between the second central surface area of the central portion and the upper surface of a protrusion of the plurality of protrusions, and the puncture resistance is greater than a reference puncture resistance of a reference substrate comprising a uniform thickness equal to the weighted average thickness and the same material as the foldable substrate.

Aspect 57. The method of any one of aspects 51-54, wherein the foldable substrate exhibits a puncture resistance measured in a Quasi-Static Puncture Test, a weighted average thickness TWA of the central portion defined as TWA=(1−AR)*TC+AR*TP, wherein AR is the area ratio, TC is the central thickness, and TP is a combined protrusion thickness defined between the second central surface area of the central portion and the upper surface of a protrusion of the plurality of protrusions, and the puncture resistance is greater than a predicted puncture resistance for the weighted average thickness based on a calibration curve from a plurality of reference substrates comprising the same material as the foldable substrate and monolithic thicknesses including values of the monolithic thicknesses greater than the weighted average thickness and less than the weighted average thickness.

Aspect 58. The method of any one of aspects 51-57, wherein a combined thickness between the second central surface area of the upper surface of a protrusion of the plurality of protrusions is less than or equal to the substrate thickness.

Aspect 59. The method of any one of aspects 51-57, wherein the first major surface extends along a first plane, a first distance is defined between the first plane and the first central surface area in the thickness direction, a protrusion height defined the first central surface area and the upper surface of a protrusion of the plurality of protrusions in the thickness direction, and the first distance is greater than or equal to the protrusion height.

Aspect 60. The method of aspect 59, wherein a ratio of the protrusion height to the first distance is from 0.30 to 1.0.

Aspect 61. The method of aspect 59, wherein the first distance is substantially equal to the protrusion height.

Aspect 62. The method of any one of aspects 38-61, further comprising chemically strengthening the foldable substrate by simultaneously exposing the first major surface, the first central surface area, and the plurality of protrusions to a molten salt solution,
wherein the chemically strengthening forms:
   a first compressive stress region extending to a first depth of compression from the first major surface in the first portion;
   a second compressive stress region extending to a second depth of compression from the first major surface in the second portion; and
   a first central compressive stress region extending to a first central depth of compression from the first central surface area.

Aspect 63. The method of aspect 62, wherein the first compressive stress region comprises a first maximum compressive stress of about 400

MegaPascals or more, and the second compressive stress region comprises a second maximum compressive stress of 400 MegaPascals or more.

Aspect 64. The method of any one of aspects 51-63, wherein the substrate thickness is in a range from about 50 micrometers to about 5 millimeters.

Aspect 65. The method of any one of aspects 51-63, wherein the substrate thickness is in a range from about 100 micrometers to about 200 micrometers.

Aspect 66. The method of any one of aspects 51-65, wherein the central thickness in a range from about 25 micrometers to about 120 micrometers.

Aspect 67. The method of any one of aspects 51-65, wherein the central thickness is in a range from about 25 micrometers to about 60 micrometers.

Aspect 68. The method of any one of aspects 38-67, wherein the foldable substrate comprises a glass-based substrate.

Aspect 69. The method of any one of aspects 38-67, wherein the foldable substrate comprises a ceramic-based substrate.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 7;

FIG. 2 is a cross-sectional view of the foldable apparatus along line 2-2 of FIG. 1 comprising a foldable substrate according to aspects;

FIG. 3 is an alternative cross-sectional view of a foldable apparatus along line 2-2 of FIG. 1 comprising a foldable substrate according to aspects;

FIG. 4 is a cross-sectional view of the foldable substrate along line 4-4 of FIG. 2;

FIG. 5 is an alternative cross-sectional view of the foldable substrate with aligned rows of protrusions;

FIG. 6 is an alternative cross-sectional view of the foldable substrate with offset rows of protrusions;

FIG. 7 is a schematic view of example foldable apparatus of aspects of the disclosure in a folded configuration wherein a schematic view of the flat configuration may appear as shown in FIG. 1;

FIG. 8 is a schematic plan view of an example consumer electronic device according to aspects;

FIG. 9 is a schematic perspective view of the example consumer electronic device of FIG. 8;

FIG. 10 is a schematic perspective view of a foldable consumer electronic product;

FIG. 11 schematically illustrates a test apparatus for performing the Pen Drop Test and/or the Quasi-Static Puncture Test;

FIG. 12 schematically illustrate a flow chart for methods of making a foldable substrate and/or foldable apparatus;

FIG. 13 schematically illustrates a step in methods comprising disposing a mask on an initial first major surface of an initial substrate;

FIG. 14 schematically illustrates a step in methods comprising disposing a patterned mask on an initial first major surface, for example, by ink-jet deposition;

FIG. 15 schematically illustrates a step in methods comprising forming a patterned mask on the initial first major surface, for example, using a laser;

FIG. 16 schematically illustrates a patterned mask in accordance with methods of the present disclosure;

FIG. 17 schematically illustrates the patterned mask in view 17 of FIG. 16;

FIG. 18 schematically illustrates another patterned mask comprising aligned rows of protrusions;

FIG. 19 schematically illustrates another patterned mask comprising offset rows of protrusions;

FIG. 20 schematically illustrates a step in methods comprising etching the initial first major surface;

FIG. 21 schematically illustrates a step in methods comprising chemically strengthening the foldable substrate;

FIG. 22 presents impact resistance as measured by the Quasi-Static Puncture Test in kilograms force (kgf) on the vertical axis (i.e., y-axis) as a function of an area ratio in percent (%) on the horizontal axis (i.e., x-axis);

FIG. 23 presents impact resistance as measured by the Quasi-Static Puncture Test in kilograms force (kgf) on the vertical axis (i.e., y-axis) as a function of thickness of the monolithic reference substrates in micrometers (μm) on the horizontal axis (i.e., x-axis) with samples having a plurality of protrusions plotted based on a corresponding minimum parallel plate distance of a monolithic reference sample;

FIG. 24 presents impact resistance as measured by the Quasi-Static Puncture Test in kilograms force (kgf) on the vertical axis (i.e., y-axis) as a function of parallel plate distance in millimeters (mm) on the horizontal axis (i.e., x-axis); and

FIG. 25 presents impact resistance as measured by the Quasi-Static Puncture Test in kilograms force (kgf) on the vertical axis (i.e., y-axis) as a function of area ratio in percent (%) on the horizontal axis (i.e., x-axis).

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

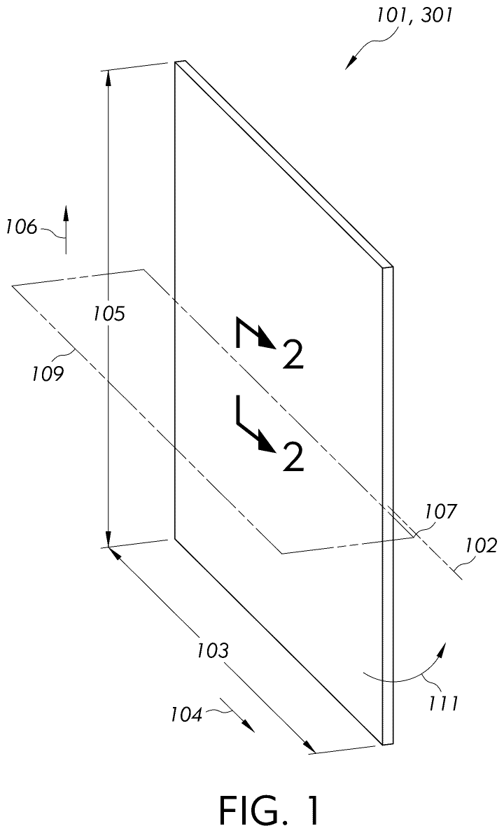

FIGS. 1-7 illustrate views of foldable apparatus 101 and 301 comprising a foldable substrate 201 having a plurality of protrusions 251 and 351 in accordance with aspects of the disclosure. Unless otherwise noted, a discussion of features of aspects of one foldable apparatus can apply equally to corresponding features of any aspect of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

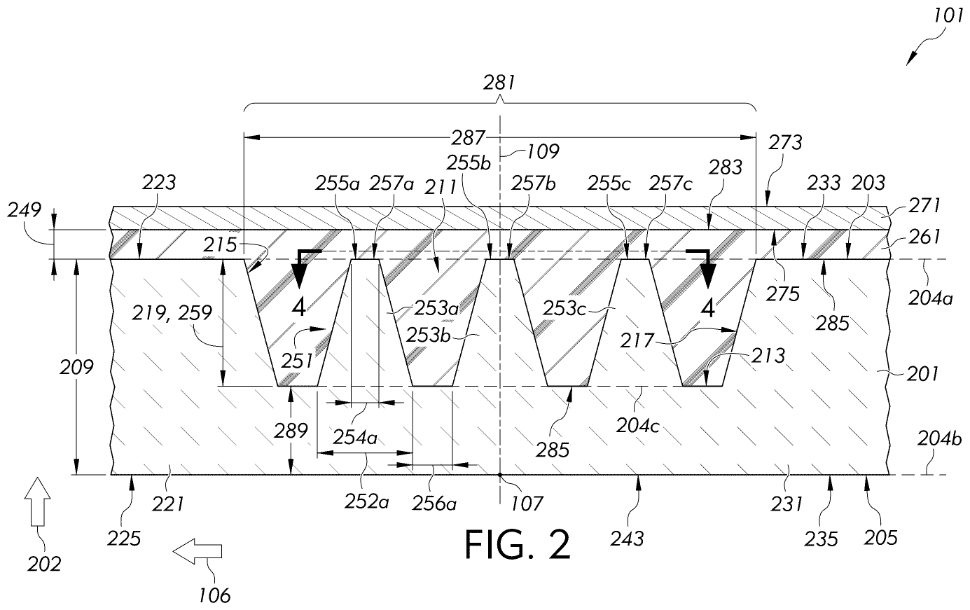

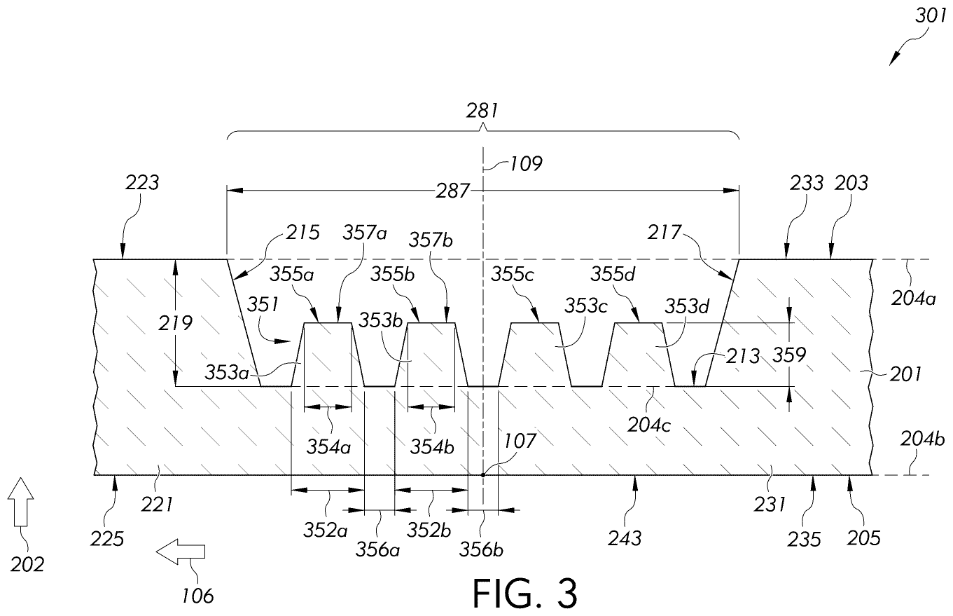

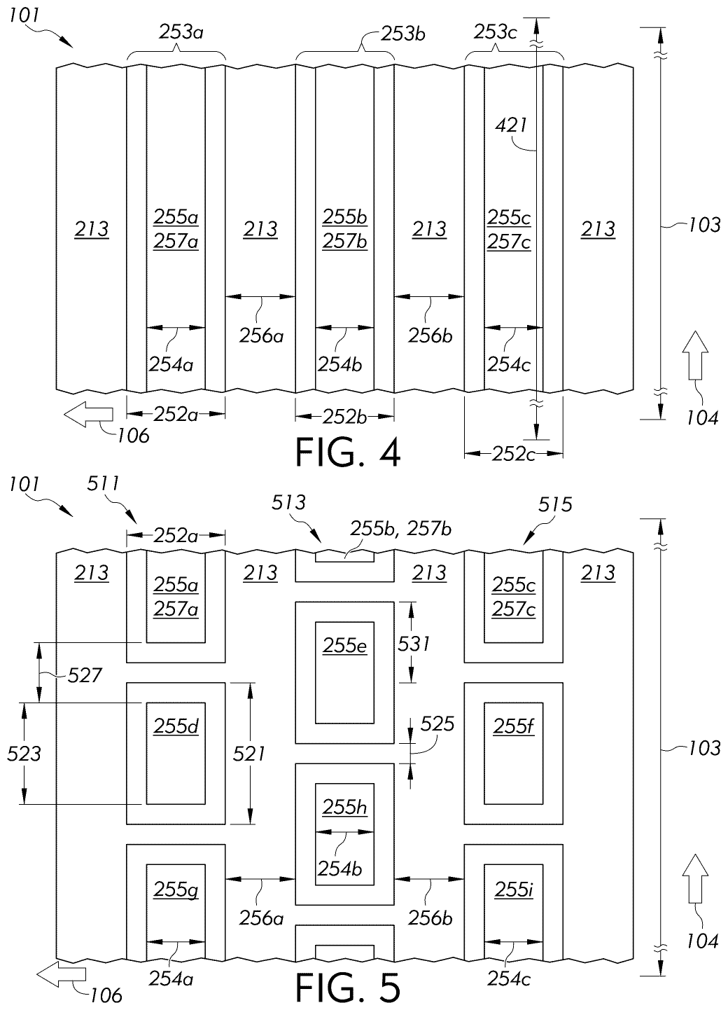

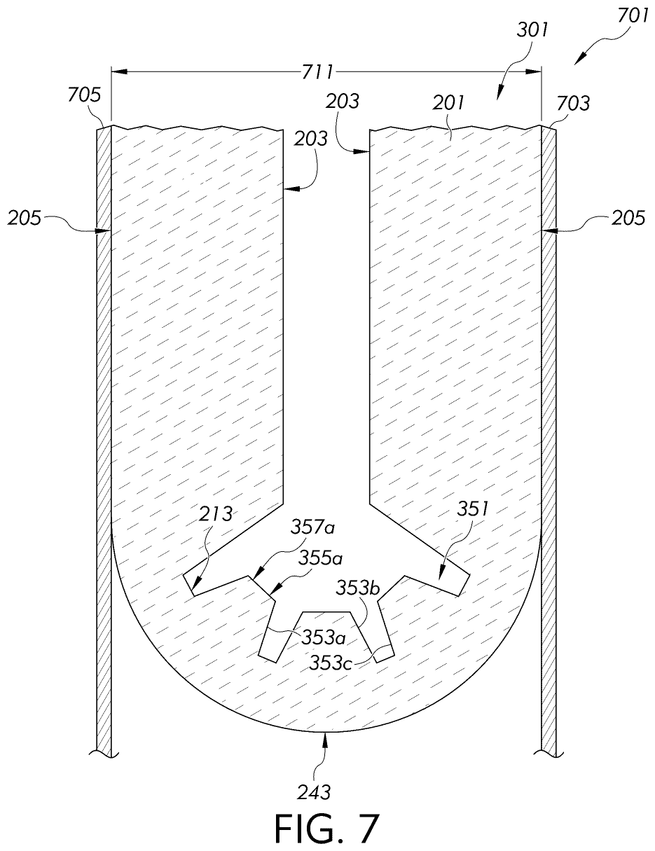

FIGS. 2-6 schematically illustrate example aspects of foldable apparatus 101 and 301 comprising the foldable substrate 201 in accordance with aspects of the disclosure in an unfolded (e.g., flat) configuration while FIG. 7 illustrates an example aspect of a foldable apparatus 301 comprising the foldable substrate 201 in accordance with aspects of the disclosure in a folded configuration. The foldable apparatus 101 and 301 and the foldable substrate 201 comprise a first portion 221 and a second portion 231 with a central portion 281 positioned therebetween. Although not shown in FIGS. 4-6, it is to be understood that the central portion 281 can be attached to a first portion 221 and/or second portion 231 similar to or identical to the corresponding portions shown in FIGS. 2-3. Although not shown, it is to be understood that the foldable substrate can be combined with one or more polymer-based portions, adhesive layers, coatings, and/or display devices as the foldable apparatus.

Throughout the disclosure, with reference to FIG. 1, the width 103 of the foldable apparatus 101 and/or 301 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus 101 and/or 301 is considered the dimension of the foldable apparatus 101 and/or 301 taken between opposed edges of the foldable apparatus 101 and/or 301 in a direction 106 perpendicular to the fold axis 102 of the foldable apparatus 101 and/or 301. It is to be understood that the direction 104 of the width 103 and/or the direction 106 of the length 105 can correspond to corresponding directions in the foldable substrate 201. In aspects, as shown in FIGS. 1-3, the foldable apparatus of any aspect of the disclosure can comprise a fold plane 109 that includes the fold axis 102 when the foldable apparatus is in the flat configuration (e.g., see FIGS. 2-3). In further aspects, as shown in FIGS. 2-3, the fold plane 109 can extend along the fold axis 102 and in a thickness direction 202 of a substrate thickness 209 when the foldable apparatus is in the flat configuration (e.g., see FIGS. 2-3). The fold plane 109 may comprise a central axis 107 of the foldable apparatus. In aspects, the foldable apparatus can be folded in a direction 111 (see FIG. 1) about the fold axis 102 extending in the direction 104 of the width 103 to form a folded configuration (e.g., see FIG. 7 corresponding to folded configurations of the flat configurations shown in FIG. 3, respectively). As shown, the foldable apparatus and/or the foldable substrate may include a single fold axis to allow the foldable apparatus and/or the foldable substrate to comprise a bifold wherein, for example, the foldable apparatus and/or the foldable substrate may be folded in half. In further aspects, the foldable apparatus and/or the foldable substrate may include two or more fold axes with each fold axis including a corresponding central portion similar or identical to the central portion 281 discussed herein. For example, providing two fold axes can allow the foldable apparatus and/or the foldable substrate to comprise a trifold wherein, for example, the foldable apparatus and/or the foldable substrate may be folded with the first portion 221, the second portion 231, and a third portion similar or identical to the first portion or second portion with the central portion 281 and another central portion similar to or identical to the central portion positioned between the first portion and the second portion and between the second portion and the third portion, respectively.

The foldable substrate 201 can comprise a glass-based substrate and/or a ceramic-based substrate having a pencil hardness of 8H or more, for example, 9H or more. As used herein, pencil hardness is measured using ASTM D 3363-20 with standard lead graded pencils. Providing a glass-based foldable substrate and/or a ceramic-based foldable substrate can enhance puncture resistance and/or impact resistance.

In aspects, the foldable substrate 201 can comprise a glass-based substrate. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In aspects, glass-based material can comprise an alkali-containing glass or an alkali-free glass, either of which may be free of lithia or not. In aspects, the glass material can be alkali-free and/or comprise a low content of alkali metals (e.g., R₂O of 10 mol % or less, wherein R₂O comprises Li₂O Na₂O, K₂O, or the more expansive list provided below). In one or more aspects, a glass-based material may comprise, in mole percent (mol %): SiO₂ in a range from 40 mol % to 80 mol %, Al₂O₃ in a range from 5 mol % to 30 mol %, B₂O₃ in a range from 0 mol % to 10 mol %, ZrO₂ in a range from 0 mol % to 5 mol %, P₂O₅ in a range from 0 mol % to 15 mol %, TiO₂ in a range from 0 mol % to 2 mol %, R₂O in a range from 0 mol % to 20 mol %, and RO in a range from 0 mol % to 15 mol %. As used herein, R₂O can refer to an alkali-metal oxide, for example, Li₂O, Na₂O, K₂O, Rb₂O, and Cs₂O. As used herein, RO can refer to MgO, CaO, SrO, BaO, and ZnO. In aspects, a glass-based substrate may optionally further comprise in a range from 0 mol % to 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, Mn₂O₇. “Glass-ceramics” include materials produced through controlled crystallization of glass. In aspects, glass-ceramics have from 1% to 99% (e.g., from 10% to 90%, or from 20% to 75%) crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes. In one or more aspects, MAS-System glass-ceramic substrates may be strengthened in Li₂SO₄ molten salt, whereby an exchange of 2Li⁺ for Mg²⁺ can occur.

In aspects, the foldable substrate 201 can comprise a ceramic-based substrate. As used herein, “ceramic-based” includes both ceramics and glass-ceramics, wherein glass-ceramics have one or more crystalline phases and an amorphous, residual glass phase. Ceramic-based materials may be strengthened (e.g., chemically strengthened). In aspects, a ceramic-based material can be formed by heating a glass-based material to form ceramic (e.g., crystalline) portions. In further aspects, ceramic-based materials may comprise one or more nucleating agents that can facilitate the formation of crystalline phase(s). In aspects, ceramic-based materials can comprise one or more oxides, nitrides, oxynitrides, carbides, borides, and/or silicides. Example aspects of ceramic oxides include zirconia (ZrO₂), zircon (ZrSiO₄), an alkali-metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlₙO₁₊ₙN₂₋ₙ, where m, n, and the resulting subscripts are all non-negative integers). Example aspects of carbides and carbon-containing ceramics include silicon carbide (SiC), tungsten carbide (WC), an iron carbide, boron carbide (B₄C), alkali-metal carbides (e.g., lithium carbide (Li₄C₃)), alkali earth metal carbides (e.g., magnesium carbide (Mg₂C₃)), and graphite. Example aspects of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example aspects of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali-metal silicide (e.g., magnesium silicide (Mg₂Si)), hafnium disilicide (HfSi₂), and platinum silicide (PtSi).

Throughout the disclosure, an elastic modulus (e.g., Young's modulus) and/or a Poisson's ratio is measured using ISO 527-1:2019. Throughout the disclosure, the Young's modulus of the glass-based materials and ceramic-based materials are measured using the resonant ultrasonic spectroscopy technique set forth in ASTM E2001-13, titled “Standard Guide for Resonant Ultrasound Spectroscopy for Defect Detection in Both Metallic and Non-metallic Parts.” In aspects, the foldable substrate 201 can comprise an elastic modulus in a range from 10 GPa to 100 GPa, from 40 GPa to 100 GPa, from 60 GPa to 100 GPa, from 60 GPa to 80 GPa, from 80 GPa to 100 GPa, or any range or subrange therebetween.

Unless otherwise indicated, transmittance values are measured using a BYK Haze-Gard Dual (BYK Gardner). In aspects, the foldable substrate 201 can be optically transparent. As used herein, “optically transparent” or “optically clear” means an average transmittance of 70% or more in the wavelength range of 400 nm to 700 nm through a 1.0 mm thick piece of a material. In aspects, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from 400 nm to 700 nm and averaging the measurements.

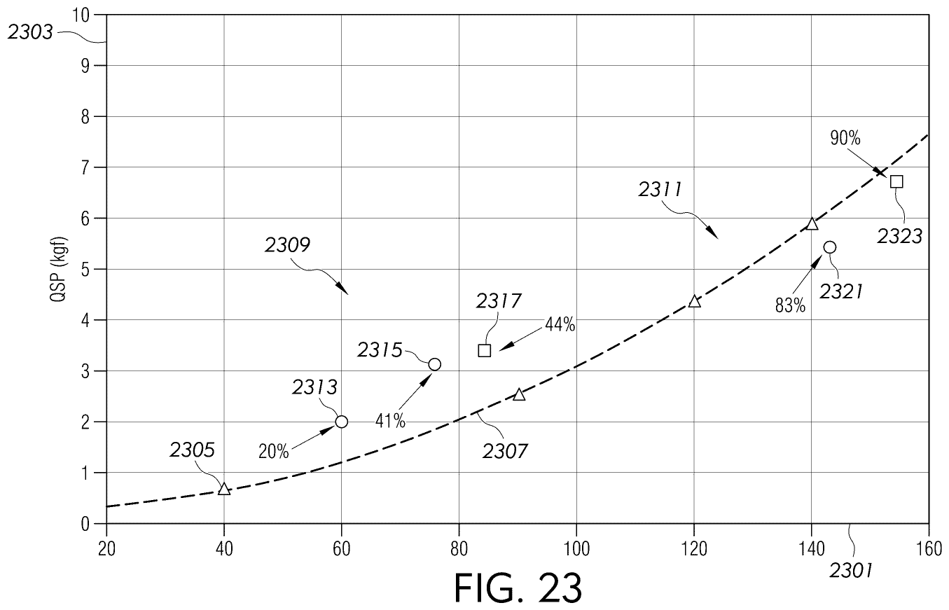

As shown in FIGS. 23, the foldable apparatus 101 and/or 301 comprise the foldable substrate 201 comprising a first major surface 203 and a second major surface 205 opposite the first major surface 203. As shown in FIGS. 2-3, the first major surface 203 can extend along a first plane 204a. The second major surface 205 can extend along a second plane 204b. In aspects, as shown in FIGS. 2-3, the first major surface 203 may be discontinuous, for example, being separated by the central portion 281 (e.g., with the central portion 281 attaching the first portion 221 to the second portion 231 with a first central surface area 213). In aspects, as shown, the second plane 204b can be parallel to the first plane 204a. As used herein, a substrate thickness 209 is defined between the first major surface 203 and the second major surface 205 as a distance between the first plane 204a and the second plane 204b in the thickness direction 202. In aspects, the substrate thickness 209 can be 10 micrometers (μm) or more, 25 μm or more, 40 μm or more, 50 μm or more, 60 μm or more, 70 μm or more, 80 μm or more, 90 μm or more, 100 μm or more, 125 μm or more, 150 μm or more, 200 μm or more, 300 μm or more, 2 millimeters (mm) or less, 1 mm or less, 800 μm or less, 500 μm or less, 300 μm or less, 200 μm or less, 180 μm or less, or 160 μm or less. In aspects, the substrate thickness 209 can be in a range from 10 μm to 2 mm, from 25 μm to 2 mm, from 40 μm to 2 mm, from 50 μm to 2 mm, from 60 μm to 2 mm, from 70 μm to 2 mm, from 70 μm to 1 mm, from 70 μm to 800 μm, from 80 μm to 500 μm, from 90 μm to 500 μm, from 100 μm to 200 μm, from 125 μm to 200 μm, from 150 μm to 200 μm, from 150 μm to 160 μm, or any range or subrange therebetween.

As shown in FIG. 2, the first portion 221 of the foldable substrate 201 can comprise a first surface area 223 and a second surface area 225 opposite the first surface area 223. The first portion 221 will now be described with reference to the foldable apparatus 101 of FIG. 2 with the understanding that such description of the first portion 221, unless otherwise stated, can also apply to any aspect of the disclosure. In aspects, as shown, the first surface area 223 can comprise a planar surface, and/or the second surface area 225 of the first portion 221 can comprise a planar surface. In further aspects, as shown, the second surface area 225 can be parallel to the first surface area 223. In aspects, as shown, the first major surface 203 can comprise the first surface area 223 and the second major surface 205 can comprise the second surface area 225. In further aspects, the first surface area 223 can extend along the first plane 204a. In further aspects, the second surface area 225 can extend along the second plane 204b. In aspects, the substrate thickness 209 can correspond to the distance between the first surface area 223 of the first portion 221 and the second surface area 225 of the first portion 221. In aspects, the substrate thickness 209 can be substantially uniform across the first surface area 223. In aspects, a first thickness defined between the first surface area 223 and the second surface area 225 can be within one or more of the ranges discussed above with regard to the substrate thickness 209. In further aspects, the first thickness can comprise the substrate thickness 209. In further aspects, the first thickness of the first portion 221 may be substantially uniform between the first surface area 223 and the second surface area 225 across its corresponding length (i.e., in the direction 106 of the length 105 of the foldable apparatus) and/or its corresponding width (i.e., in the direction 104 of the width 103 of the foldable apparatus). As discussed above, it is to be understood that the foldable apparatus 101 and/or 301 shown in FIGS. 2-3 can also comprise a first portion 221 similar to or identical to that described above in this paragraph attached to the central portion 281.

As shown in FIG. 2, the second portion 231 of the foldable substrate 201 can comprise a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspect of the disclosure. In aspects, as shown, the third surface area 233 of the second portion 231 can comprise a planar surface, and/or the fourth surface area 235 of the second portion 231 can comprise a planar surface. In further aspects, the third surface area 233 of the second portion 231 can be in a common plane with the first surface area 223 of the first portion 221. In further aspects, as shown, the fourth surface area 235 can be parallel to the third surface area 233. In further aspects, the fourth surface area 235 of the second portion 231 can be in a common plane with the second surface area 225 of the first portion 221. A second thickness can be defined between the third surface area 233 of the second portion 231 and the fourth surface area 235 of the second portion 231. In aspects, the second thickness can be within the range discussed above with regard to the substrate thickness 209. In further aspects, the second thickness can comprise the substrate thickness 209. In further aspects, as shown, the second thickness can be substantially equal to the substrate thickness 209. In aspects, the second thickness of the second portion 231 may be substantially uniform between the third surface area 233 and the fourth surface area 235. As discussed above, it is to be understood that the foldable apparatus 101 and/or 301 shown in FIGS. 2-3 can also comprise a second portion 231 similar to or identical to that described above in this paragraph attached to the central portion 281.

As shown in FIGS. 2-3, the foldable substrate 201 comprises a central portion 281 positioned between the first portion 221 and the second portion 231. In aspects, as shown in FIGS. 2-3, the central portion 281 can comprise a first central surface area 213 and/or a second central surface area 243 opposite the first central surface area 213. In aspects, as shown in FIGS. 2-3, the central portion can further comprise a first transition surface area 215 and/or a second transition surface area 217 attaching the first central surface area 213 to the first portion 221 or the second portion 231, respectively. In aspects, although not labeled, a transition width of the first transition surface area 215 and/or the second transition surface area 217 (between the first central surface area 213 and the first portion 221 or the second portion 231) in the direction 106 can be 100 μm or more, 200 μm or more, 300 μm or more, 500 μm or more, 700 μm or more, 1 mm or more, 7 mm or less, 6 mm or less, 5 mm or less, 4 mm or less, 3 mm or less, 1 mm or less, 800 μm or less, or 600 μm or less. In further aspects, the transition width can be in a range from 100 μm to 7 mm, from 100 μm to 6 mm, from 100 μm to 5 mm, from 100 μm to 4 mm, from 200 μm to 3 mm, from 300 μm to 1 mm, from 500 μm to 1 mm, from 500 μm to 800 μm, from 500 μm to 600 μm, or any range or subrange therebetween.

In aspects, as shown in FIG. 2, the central portion 281 comprises a central thickness 289 defined a minimum thickness of the foldable substrate 201 in a thickness direction 202 of the substrate thickness 209 for the central portion 281 of the foldable substrate 201. Consequently, the central thickness 289 is less than the substrate thickness 209. For example, as shown in FIG. 2, the central thickness 289 occurs between a first central surface area 213 and a second central surface area 243. Also, the first central surface area 213 excludes the plurality of protrusions 251 (discussed below) extending therefrom. In further aspects, the first central surface area 213 (excluding the plurality of protrusions 251) can be substantially planar and/or extend along a third plane 204c that can, in even further aspects, be substantially parallel to the first plane 204a and/or the second plane 204b.

In aspects, the central thickness 289 can be 1 μm or more, 5 μm or more, 10 μm or more, 25 μm or more, 40 μm or more, 120 μm or less, 100 μm or less, 80 μm or less, 60 μm or less, or 50 μm or less. In aspects, the central thickness 289 can be in a range from 1 μm to 120 μm, from 5 μm to 120 μm, from 10 μm to 120 μm, from 10 μm to 120 μm, from 25 μm to 120 μm, from 25 μm to 100 μm, from 25 μm to 80 μm, from 25 μm to 60 μm, from 40 μm to 60 μm, or any range or subrange therebetween. In aspects, the central thickness 289 can be less than the substrate thickness 209 by 10 μm or more, 20 μm or more, 30 μm or more, 40 μm or more, 50 μm or more, or 60 μm or more. In aspects, the central thickness 289 as a percentage of the substrate thickness 209 can be 0.5% or more, 1% or more, 2% or more, 5% or more, 6% or more, 10% or more, 25% or more, 40% or more, 50% or more, 66% or more, 75% or more, 80% or more, 90% or less, 88% or less, 85% or less, 82% or less, 80% or less, 80% or less, 75% or less, 66% or less, 60% or less, 45% or less, 30% or less, 20% or less, 13% or less, 10% or less, or 8% or less. In aspects, the central thickness 289 as a percentage of the substrate thickness 209 can be in a range from 0.5% to 40%, from 0.5% to 30%, from 0.5% to 20%, from 0.5% to 13%, from 1% to 13%, from 1% to 10%, from 2% to 10%, from 2% to 8%, from 5% to 8%, from 6% to 8%, or any range or subrange therebetween. Alternatively, in aspects, the central thickness 289 as a percentage of the substrate thickness 209 can be in a range from 10% to 90%, from 25% to 90%, from 40% to 88%, from 50% to 88%, from 66% to 85%, from 75% to 85%, from 80% to 82%, or any range or subrange therebetween.

As shown in FIGS. 2-3, the first central surface area 213 can be recessed from the first major surface 203 by a first distance 219. In further aspects, the first distance 219 can be 30 μm or more, 40 μm or more, 50 μm or more, 70 μm or more, 100 μm or more, 3 mm or less, 1 mm or less, 800 μm or less, 500 μm or less, 300 μm or less, 100 μm or less, or 60 μm or less. In further aspects, the first distance 219 can be in a range from 30 μm to 3 mm, from 30 μm to 1 mm, from 30 μm to 800 μm, from 30 μm to 500 μm, from 40 μm to 300 μm, from 50 μm to 100 μm, from 50 μm to 60 μm, or any range or subrange therebetween. In aspects, the first distance 219 can correspond to a distance (in the thickness direction 202) between the first plane 204a and the third plane 204c. In aspects, as shown, the second central surface area 243 can be part of the second major surface 205. In aspects, as shown, the second central surface area 243 can be flush with the second major surface 205.

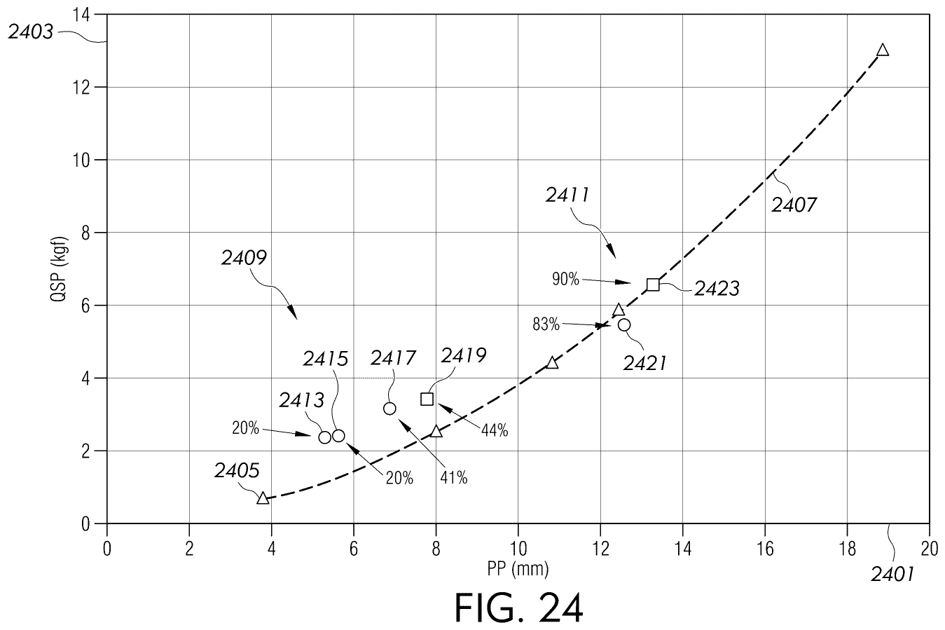

The inventors of the present application have unexpectedly determined that providing a plurality of protrusions can improve impact resistance (e.g., as measured in the Quasi-Static Puncture Test) while allowing the foldable substrate and/or foldable substrate to still attain low parallel plate distances. Specifically, as discussed below with reference to FIG. 24, area ratios have unexpectedly been identified where the impact resistance (e.g., as measured in the Quasi-Static Puncture Test) is greater than a reference sample having a monolithic thickness with the same parallel plate distance (e.g., minimum parallel plate distance) (where the parallel plate distance and impact resistance of the reference sample is either directly measured experimentally or based on a calibration curve from a plurality of reference substrates), which demonstrates that the plurality of protrusion can increase impact resistance without negatively impacting foldability (e.g., parallel plate distance). Also, area ratios have unexpectedly been identified where the impact resistance (e.g., as measured in the Quasi-Static Puncture Test) is greater than a reference sample having a monolithic thickness equal to a weighted average thickness (defined below) (where the impact resistance of the reference sample is either directly measured experimentally or based on a calibration curve from a plurality of reference substrates), which demonstrates that the plurality of protrusion can increase impact resistance beyond what would be achieved for a substrate with the same weighted average thickness.

FIGS. 2-3 show cross-sectional views of the foldable apparatus 101 and/or 301 comprising a plurality of protrusions 251 and/or 351 in accordance with aspects of the disclosure. In aspects, as shown in FIGS. 2-3, the plurality of protrusions 251 and/or 351 can extend from the first central surface area 213, although the plurality of protrusions can extend from both sides of the foldable substrate in further aspects. In further aspects, as shown, the central portion 281 including the protrusions 251 and/or 351 is defined based on the local thickness profile of the first central surface area 213 excluding the plurality of protrusions 251 and/or 351, where the thickness increases from a local thickness equal to the central thickness (e.g., central thickness 289 shown in FIG. 2). In aspects, as shown in FIG. 2, a local thickness of the central portion 281 (e.g., profile of first central surface area 213) excluding the plurality of protrusions 351 can be substantially constant across the first central surface area 213 (e.g., excluding any transition surface areas).

Throughout the disclosure, a protrusion of the plurality of protrusions extends from the first central surface area by at least 5 μm in the thickness direction. For example, with reference to FIG. 2, protrusion 253a of the plurality of protrusions 251 extends from the first central surface area 213 (excluding the plurality of protrusions 251—e.g., third plane 204c) in the thickness direction 202 by at least 5 μm (i.e., protrusion height 259 is greater than 5 μm). In aspects, the protrusions 253a-253c and/or 353a-353d of the plurality of protrusions 251 and/or 351 can extend from the first central surface area 213 in the thickness direction 202 by at least 10 μm, 20 μm or more, 25 μm or more, 30 μm or more, 35 μm or more, 40 μm or more, or 50 μm or more. As used herein, a protrusion height of a protrusion of the plurality of protrusions is defined as a maximum distance between the first central surface area and an upper surface of the corresponding protrusion in the thickness direction. For example, with reference to FIG. 2, the protrusion height 259 of the protrusion 253a of the plurality of protrusions 251 is a maximum distance in the thickness direction 202 between the first central surface area 213 (excluding the plurality of protrusions 251—e.g., third plane 204c) and the upper surface 257a-257c (e.g., outer periphery) of the corresponding protrusion 253a. In aspects, as shown in FIGS. 2-3, the protrusion height 259 and/or 359 can be substantially uniform across the plurality of protrusions 251 and/or 351, although the protrusion heights may vary among the plurality of protrusions in other aspects.

In aspects, as shown in FIGS. 2-3, the first distance 219 that the first central surface area 213 is recessed from the first major surface 203 can be greater than or equal to the protrusion height 259 and/or 359 of one or more protrusions 253a-253c and/or 353a-353d (e.g., all) of the plurality of protrusions 251 and/or 351. In further aspects, a ratio of the protrusion height 259 and/or 359 to the first distance 219 (as a percentage) can be 30% or more, 40% or more, 50% or more, 66% or more, 75% or more, 80% or more, 85% or more, 90% or more, 95% or more, 100% or less, 98% or less, 95% or less, 92% or less, 90% or less, 85% or less, 80% or less, 75% or less, 70% or less, 65% or less, 60% or less, or 50% or less. In further aspects, a ratio of the protrusion height 259 and/or 359 to the first distance 219 (as a percentage) can be in a range from 30% to 100%, from 40% to 98%, from 50% to 95%, from 66% to 92%, from 75% to 90%, from 80% to 85%, or any range or subrange therebetween. In further aspects, as shown in FIG. 3, the protrusion height 359 can be less than the first distance 219. Alternatively, as shown in FIG. 2, the protrusion height 259 can be substantially equal to the first distance 219. In aspects, a combined thickness of the central thickness 289 and the protrusion height 259 and/or 359 can be less than or equal to the substrate thickness 209. In further aspects, as shown in FIG. 3, the combined thickness of the central thickness 289 and the protrusion height 359 can be less than the substrate thickness 209. Alternatively, as shown in FIG. 2, the combined thickness of the central thickness 289 and the protrusion height 259 can be substantially equal to the substrate thickness 209.

In aspects, as shown in FIGS. 2-3 and 20-21, the shape of a cross-section of one or more protrusions 253a-253c and/or 353a-353d of the plurality of protrusions 251 and/or 351 can be substantially polygonal (e.g., linear and/or quadrilateral), although the shape of the cross-section can be curved (e.g., elliptical), curvilinear, or a combination thereof in further aspects. In aspects, a cross-sectional shape of a protrusion of the plurality of protrusions can have rounded corners (e.g., between inclined, side surfaces and an upper surface therebetween—rather than the angular corners shown herein). Providing rounded corners for the cross-sectional shape of a tooth of the plurality of protrusions can decrease stress concentrations at the corners of the protrusion, which can decrease a maximum bending stress associated with folding to a predetermined parallel plate distance and/or increase a reliability of folding the foldable substrate and/or foldable apparatus. Also, providing a plurality of protrusions (e.g., comprising substantially the substrate thickness) can increase a puncture resistance of the central portion (e.g., due to the increased thickness of the plurality of protrusions relative to the first central surface area 213) while the central portion (excluding the plurality of protrusions) can still facilitate folding of the foldable apparatus and/or foldable substrate. In further aspects, providing a plurality of substantially constant local thicknesses (e.g., substantially equal to the central thickness 289) between corresponding adjacent pairs of protrusions of the plurality of protrusions can simplify manufacturing, for example, enabling the local thickness between an adjacent pair of protrusions to be formed in a single etching step (e.g., with the portions corresponding to the adjacent pair of protrusions being masked).

Throughout the disclosure, the upper surface of a protrusion is defined as portions of the surface of the protrusion that is within 5 μm in the thickness direction of an outer periphery of the protrusion corresponding to the protrusion height between the first central surface area and the corresponding outer periphery of the corresponding protrusion. With reference to FIG. 2, the upper surface 257a of the protrusion 253a is the portion of the outer surface 255a of the protrusion that is within 5 μm in the thickness direction 202 (e.g., vertical distance in FIG. 2) of an outer periphery (e.g., the portion of the outer surface 255a extending along the first plane 204a) that is positioned the protrusion height 259 from the first central surface area 213. Consequently, the upper surface 257a of protrusion 253a includes the substantially planar portion (e.g., extending along the first plane 204a) and additional portions of the outer surface 255a to either side that are within 5 μm in the thickness direction 202 of the substantially planar portion corresponding to the outer periphery of the protrusion 253a. For simplicity, the upper surface 257a is shown as being substantially coextensive with the substantially planar portion with the understanding that the outer surface may in-fact include a portion of the upper surface to either side (e.g., curved and/or inclined portions adjacent to the outer periphery).

In aspects, as shown in FIGS. 2-6, an upper width 254a, 354a, and/or 354b of an upper surface 257a, 357a, and/or 357b of a protrusion 253a, 353a, and/or 353b of the plurality of protrusions 251 and/or 351 is measured in the direction 106 between the first portion 221 and the second portion 231. In aspects, the upper width 254a, 354a, and/or 354b can be 20 μm or more, 30 μm or more, 40 μm or more, 50 μm or more, 65 μm or more, 80 μm or more, 100 μm or more, 150 μm or more, 200 μm or more, 250 μm or more, 300 μm or more, 400 μm or more, 500 μm or more, 1 mm or less, 800 μm or less, 600 μm or less, 500 μm or less, 400 μm or less, 310 μm or less, 260 μm or less, 180 μm or less, 130 μm or less, 100 μm or less, or 80 μm or less. In aspects, the upper width 254a, 354a, and/or 354b can be in a range from 20 μm to 1 mm, from 30 μm to 800 μm, from 40 μm to 600 μm, from 50 μm to 500 μm, from 65 μm to 400 μm, from 80 μm to 310 μm, from 100 μm to 260 μm, from 150 μm to 180 μm, or any range or subrange therebetween. In preferred aspects, the upper width 254a, 354a, and/or 354b can be from 20 μm to 1 mm, from 80 μm to 310 μm, or from 150 μm to 250 μm. In aspects, as shown in FIG. 3, the upper width 354a of a protrusion 353a can be substantially equal to the upper width 354b of an adjacent protrusion 353b of the plurality of protrusions, and/or the upper width 354a and/or 354b of each protrusion 353a-353d of the plurality of protrusions 351 can be substantially the same, although in other aspects, an upper width of protrusions can vary in other aspects, for example, with protrusions closer to the fold plane 109 having smaller upper widths than protrusions further from the fold plane 109. Similarly, as shown in FIGS. 4-6, the upper width 254a (of upper surface 257a, 257d, and/or 257g) of a protrusion (corresponding to outer surface 255a, 255d, and/or 255g) can be substantially equal to the upper width 254b and/or 254c (of upper surface 257b, 257c, 257e, 257f, 257h and/or 257i) of other protrusions (corresponding to protrusions 255b, 255c, 255e, 255f, 255h, and/or 255i) of the plurality of protrusions. In aspects, as shown in FIG. 3, the midline (e.g., dashed line, fold plane 109) may not impinge a protrusion of the plurality of protrusions 351. Alternatively, in aspects, as shown in FIG. 2, the midline (e.g., dashed line, fold plane 109) may impinge a protrusion 253b of the plurality of protrusions 251. Providing a plurality of protrusions arranged such that there is not a protrusion of the plurality of protrusions impinged by the midline (e.g., fold plane 109) can decrease a bend-induced stress on the foldable substrate.

In aspects, as shown in FIGS. 2-6, a full width 252a, 352a, and/or 352b of a protrusion 253a, 353a, and/or 353b of the plurality of protrusions 251 and/or 351 is measured as a maximum width of the protrusion (e.g., outer surface 255a-255c, 255a-255i, and/or 355a-355d) in the direction 106 between the first portion 221 and the second portion 231. In aspects, an absolute value of a difference between the upper width 254a, 354a, and/or 354b and the full width 252a, 352a, and/or 352b can be 1 mm or less, 800 μm or less, 500 μm or less, 300 μm or less, 250 μm or less, 200 μm or less, 180 μm or less, 150 μm or less, 10 μm or more, 25 μm or more, 40 μm or more, 60 μm or more, 80 μm or more, 100 μm or more, 120 μm or more, or 140 μm or more. In aspects, an absolute value of a difference between the upper width 254a, 354a, and/or 354b and the full width 252a, 352a, and/or 352b can be in a range from 10 μm to 1 mm, from 10 μm to 800 μm, from 25 μm to 500 μm, from 25 μm to 300 μm, from 40 μm to 250 μm, from 60 μm to 200 μm, from 80 μm to 180 μm, from 100 μm to 150 μm, from 120 μm to 150 μm, or any range or subrange therebetween. In aspects, the full width can be within one or more of the ranges discussed above for the upper width. In aspects, as shown in FIG. 3, the full width 352a of a protrusion 353a can be substantially equal to the full width 352b of an adjacent protrusion 353b of the plurality of protrusions, and/or the full width 352a and/or 352b of each protrusion 353a-353d of the plurality of protrusions 351 can be substantially the same, although in other aspects, an full width of protrusions can vary in other aspects, for example, with protrusions closer to the fold plane 109 having smaller full widths than protrusions further from the fold plane 109. Similarly, as shown in FIGS. 4-6, the full width 252a of a protrusion (corresponding to outer surface 255a, 255d, and/or 255g) can be substantially equal to the full width 252b and/or 252c of other protrusions (corresponding to protrusions 255b, 255c, 255e, 255f, 255h, and/or 255i) of the plurality of protrusions.

In aspects, as shown in FIGS. 2-6, a gap width 256a, 356a, and/or 356b can be defined between an adjacent pair of protrusions (e.g., protrusions 253a and 253b, 353a and 353b, and/or 353b and 353c). For example, with reference to FIG. 3, gap width 356a is measured between the adjacent pair of protrusions 353a and 353b. Likewise, gaps associated with gap width 356a and 356b are adjacent to protrusion 353b. In further aspects, as shown in FIGS. 2-6, the gap width 256a-256b and/or 356a-356b between an adjacent pair of protrusions can be substantially the same for all adjacent pairs of protrusions (e.g., of the plurality of protrusions) in the central portion 281. Alternatively, although not shown, distances between adjacent pairs of protrusions for different adjacent pairs of protrusions can be different as the distance of the adjacent pair of protrusions from the midline (e.g., fold plane 109) changes. For example, the distance between a first adjacent pair of protrusions can be less than a distance between a second adjacent pair of protrusions, where the first adjacent pair of protrusions is closer to the midline (e.g., dashed line, fold plane 109) than the second adjacent pair of protrusions is to the midline. Alternatively, for example, the distance between adjacent pairs of protrusions can be greater than a distance between a second adjacent pair of protrusions, wherein the first adjacent pair of protrusions is closer to the midline (e.g., dashed line, fold plane 109) than the second adjacent pair of protrusions is to the midline. In further aspects, the gap width 256a-256b and/or 356a-356b can be 10 μm or more, 50 μm or more, 80 μm or more, 100 μm or more, 120 μm or more, 150 μm or more, 200 μm or more, 1 mm or less, 800 μm or less, 500 μm or less, 400 μm or less, 300 μm or less, 250 μm or less, 200 μm or less, or 180 μm or less. In further aspects, the gap width 256a-256b and/or 356a-356b can be in a range from 10 μm to 1 mm, from 50 μm to 800 μm, from 80 μm to 500 μm, from 100 μm to 400 μm, from 120 μm to 300 μm, from 150 μm to 250 μm, or any range or subrange therebetween. Although not explicitly labeled, a minimum distance between the upper surfaces of adjacent protrusions can be within one or more of the ranges discussed for the gap width. The minimum distance between the upper surfaces of adjacent protrusions can be from 150 μm to 1 mm, from 200 μm to 800 μm, from 250 μm to 600 μm, from 300 μm to 500 μm, or any range or subrange therebetween.

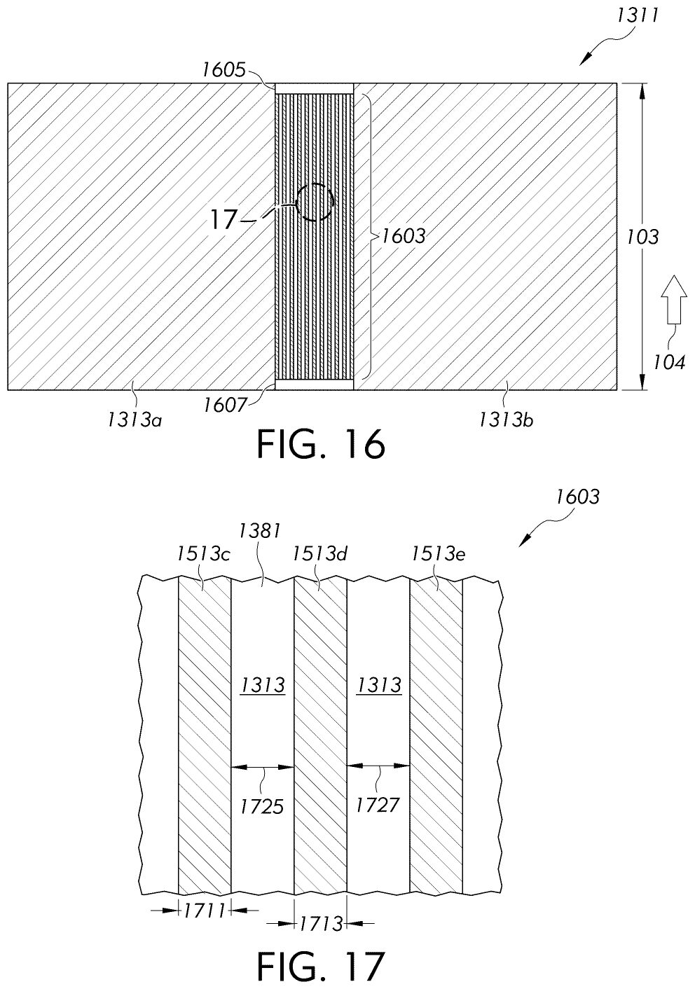

FIGS. 4-6 show various patterns for the plurality of protrusions in foldable apparatus 101 and/or 301 and the first central surface area 213. In aspects, as shown in FIG. 4, the plurality of protrusions can be aligned in a row extending in the direction 106 (e.g., between the first portion 221 and the second portion 231 shown in FIGS. 2-3). In further aspects, as shown, the plurality of protrusions can be arranged in a single row (e.g., one-dimensional row). In further aspects, a length 421 of one or more of the protrusions 253a-253c in a direction 104 (perpendicular to the direction 106), as a percentage of the width 103 of the foldable substrate 201 and/or the foldable apparatus 101 and/or 301, can be 50% or more, 66% or more, 75% or more, 80% or more, 85% or more, 90% or more, 92% or more 95% or more, 100% or less, 99% or less, 98% or less, 95% or less, 92% or less, 90% or less, 85% or less, 80% or less, or 75% or less. In further aspects, a length 421 of one or more of the protrusions 253a-253c in a direction 104 (perpendicular to the direction 106), as a percentage of the width 103 of the foldable substrate 201 and/or the foldable apparatus 101 and/or 301, can be from 50% to 100%, from 66% to 99%, from 75% to 98%, from 80% to 95%, from 85% to 92%, from 90% to 92%, or any range or subrange therebetween. As indicated by portions 1605 and 1607 in FIG. 16, the plurality of protrusions may not extend all the way to the ends (in direction 104) of the central portion, although the plurality of protrusions can extend for the entire width of the foldable substrate and/or foldable apparatus in the central portion in further aspects.

In aspects, as shown in FIGS. 4-6, one or more protrusions (e.g., protrusions 253a-253c and/or protrusions 253a-253i) of the plurality of protrusions comprise an upper width (e.g., upper width 254a-254c) of the upper surface (e.g., upper surface 257a-257c and/or upper surface 257a-257i) within one or more of the corresponding ranges for the upper width discussed above. In aspects, as shown in FIGS. 4-6, one or more protrusions (e.g., protrusions 253a-253c and/or protrusions 253a-253i) of the plurality of protrusions comprise a full width (e.g., full width 252a-252c) of the outer surface (e.g., outer surface 255a-255c and/or outer surface 255a-255i) within one or more of the corresponding ranges for the full width discussed above. In aspects, as shown in FIGS. 4-6, a gap width 256a-256b between adjacent pairs of protrusions in the direction 106 (or the full width) can be within one or more of the corresponding ranges (e.g., gap width or full width, respectively) discussed above.

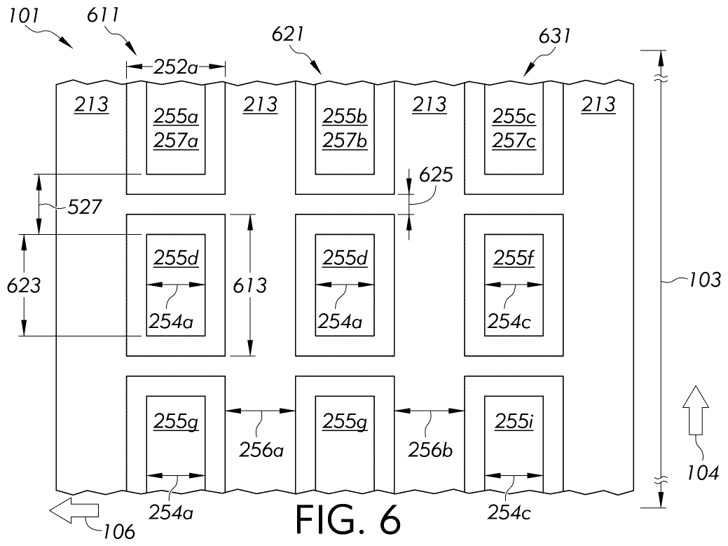

As shown in FIGS. 5-6, the plurality of protrusions can be arranged in a two-dimensional array with rows extending in the direction 106 (between the first portion and the second portion) and columns extending in the direction 104 (perpendicular to the direction 104), where adjacent rows and/or columns can be aligned or offset. In aspects, as shown, a column 511, 513, 515, 611, 621, or 631 can comprise three or more protrusions, and/or each row can comprise at least three protrusions. In aspects, as shown in FIG. 6, the plurality of protrusions in a first column 611 can be aligned with corresponding protrusions of a second column 621 of the plurality of columns in the two-dimensional array (e.g., an offset 531 in FIG. 5 of 0). In aspects, as shown in FIG. 5, the plurality of protrusions in a first column 511 can be offset from the plurality of protrusions in a second column 513 by an offset 531. In aspects, the offset 531, as a percentage of the upper length 623, can be 15% or more, 30% or more, 40% or more, 50% or more, 60% or more, 66% or more, 75% or more, 125% or less, 100% or less, 85% or less, 70% or less, 60% or less, 50% or less, 40% or less, 33% or less, or 25 or less. In aspects, the offset 531, as a percentage of the upper length 623, can be in a range from 15% to 125%, from 30% to 100%, from 30% to 85%, from 40% to 70%, from 50% to 60%, or any range or subrange therebetween.

In aspects, as shown in FIGS. 5-6, a protrusion (corresponding to outer surface 255d) of the plurality of protrusions comprises an upper length 523 and/or 623 of the upper surface 257d. In further aspects, as shown, the upper length 523 and/or 623 can be greater than or equal to the upper width 254a. In further aspects, the upper length 523 and/or 623 can be 1 mm or more, 2 mm or more, 3 mm or more, 4 mm or more, 5 mm or more, 15 mm or less, 10 mm or less, 8 mm or less, 7 mm or less, 6 mm or less, or 5 mm or less. In aspects, the upper length 523 and/or 623 can be from 1 mm to 15 mm, from 2 mm to 10 mm, from 2 mm to 8 mm, from 3 mm to 7 mm, from 3 mm to 6 mm, from 4 mm to 5 mm, or any range or subrange therebetween. In aspects, as shown, a protrusion of the plurality of protrusions comprises a full length 521 and/or 613 of the outer surface 255d that can be within one more of the range discussed above for the upper length. In aspects, an absolute value of a difference between the full length 521 and/or 613 and the upper length 523 and/or 623 can be substantially equal to an absolute value of a difference between the full width 252a and the upper width 254a.

In aspects, as shown in FIGS. 5-6, an adjacent pair of protrusions in the same column (e.g., column 511, 513, 515, 611, 621, or 631) can be separated by a gap length 525 and/or 625 in the direction 104. In aspects, as shown in FIGS. 5-6, the upper surfaces 257a-257i of an adjacent pair of protrusions in the same column (e.g., column 511, 513, 515, 611, 621, or 631) can be separated by a minimum distance 527 in the direction 104. In aspects, the gap length 625 and/or the minimum distance 527 can be within one or more of the ranges discussed above for the gap width 256a, 256b, 356a, and/or 356b. In aspects, an absolute value of a difference between the minimum distance 527 and the gap length 625 can be substantially equal to an absolute value of a difference between the full width 252a and the upper width 254a.

Throughout the disclosure, a “total protrusion area” is a sum of an area of the upper surface of each protrusion of the plurality of protrusions. For example, with reference to FIG. 4, the total protrusion area (for protrusions in the region shown) is the sum of an area of upper surface 257a for protrusion 253a, upper surface 257b for protrusion 253b, and upper surface 257c for protrusion 253c. With reference to FIGS. 5-6, the total protrusion area (for protrusions in the region shown) is the sum of the surface area of upper surfaces 257a-257i. Throughout the disclosure, a “total central area” is an area of the central portion in a plane perpendicular to the thickness direction and impinging the first central surface area. For example, with reference to FIGS. 4-6, the total central area is the entire area shown (that is all part of the central portion) not just the portions of the first central surface area 213 since the central portion includes portions where the plurality of protrusions are. With reference to FIG. 2, the total central area is an area of the central portion projected onto the third plane 204c that is perpendicular to the thickness direction 202 and impinges the first central surface area 213; again, the total central area is the central width 287 of the central portion times the length (dimension not shown in FIG. 2—see direction 104 in FIGS. 4-6 and/or width 103 of the foldable substrate 201 and/or foldable apparatus 101 and/or 301). As used herein, an “area ratio” is the total protrusion area divided by the total central area. In aspects, the area ratio can be 0.10 or more, 0.15 or more, 0.20 or more, 0.25 or more, 0.30 or more, 0.35 or more, 0.40 or more, 0.70 or less, 0.65 or less, 0.60 or less, 0.55 or less, 0.50 or less, 0.45 or less, or 0.40 or less. In aspects, the area ratio can be from 0.10 to 0.70, from 0.15 to 0.65, from 0.20 to 0.60, from 0.20 to 0.55, from 0.25 to 0.50, from 0.30 to 0.45, from 0.35 to 0.40, or any range or subrange therebetween. In preferred aspects, the area ratio can be in a range from 0.10 to 0.70, from 0.20 to 0.60, or from 0.25 to 0.50. As discussed herein, providing an area ratio from 0.10 to 0.70 (e.g., from 0.20 to 0.60, or from 0.25 to 0.50) can unexpectedly provide improved impact resistance (e.g., as measured in the Quasi-Static Puncture Test), for example, relative to a reference substrate with the same parallel plate distance or with the same weighted average thickness.

Aspects of the disclosure can comprise a consumer electronic product. The consumer electronic product can comprise a front surface, a back surface, and a side surface(s). The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of a portion of the housing or the cover substrate comprises the foldable apparatus and/or the foldable substrate discussed throughout the disclosure. The consumer electronic product can comprise a portable electronic device, for example, a smartphone, a tablet, a wearable device, or a laptop.

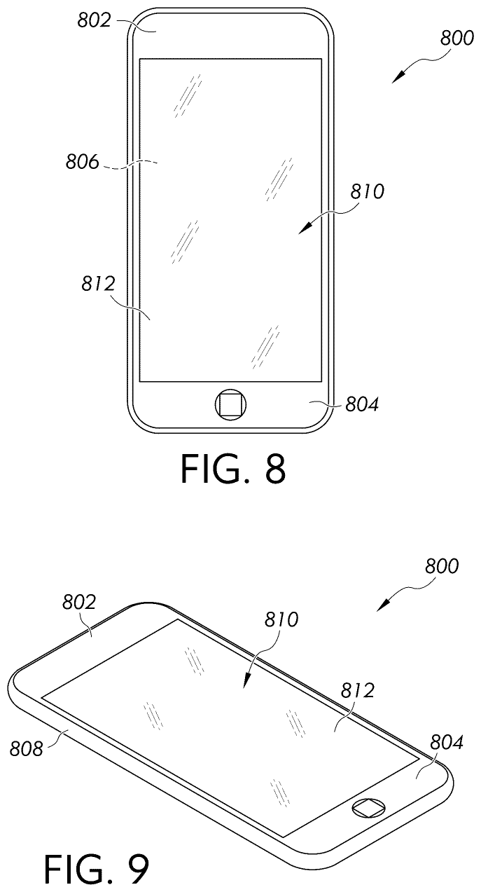

The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the foldable apparatus disclosed herein is shown in FIGS. 8-9. Specifically, FIGS. 8-9 show a consumer electronic device 800 including a housing 802 having front 804, back 806, and a side surface 808. Although not shown, the consumer electronic device can comprise electrical components that are at least partially inside or entirely within the housing. For example, electrical components include at least a controller, a memory, and a display. As shown in FIGS. 8-9, the display 810 can be at or adjacent to the front surface of the housing 802. The consumer electronic device can comprise a cover substrate 812 at or over the front surface of the housing 802 such that it is over the display 810. In aspects, at least one of the cover substrate 812 or a portion of housing 802 may include any of the foldable apparatus disclosed herein, for example, the foldable substrate.

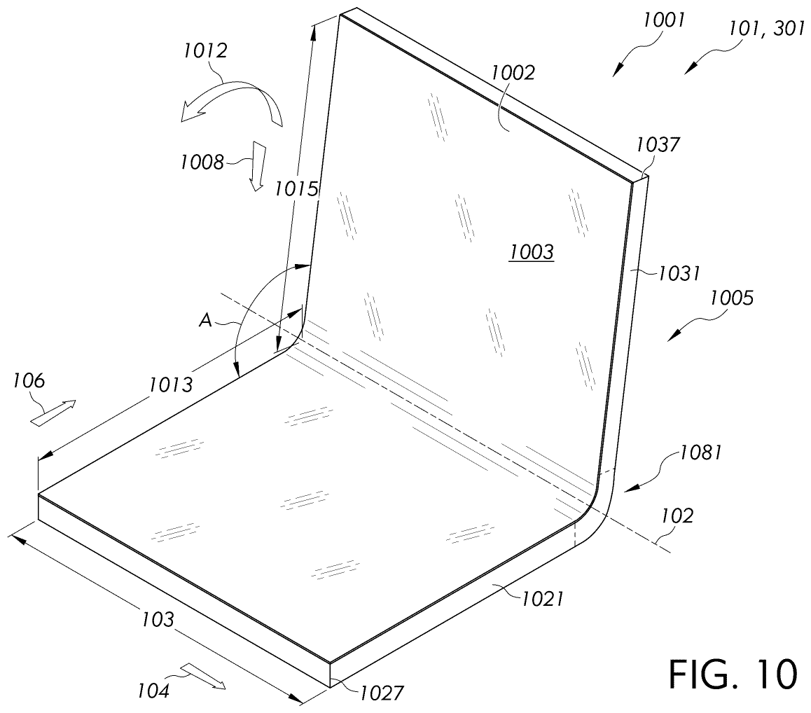

Also, FIG. 10 schematically shows a perspective view of a consumer electronic product 1001 that is foldable. The consumer electronic product 1001 can include the foldable apparatus 101 and/or 301 and/or the foldable substrate 201 in accordance with aspects of the present disclosure. As shown, the consumer electronic product 1001 can include a front surface 1003 and a side surface 1005. The consumer electronic product 1001 can include electronic components, including a display 1002 that can be viewed through the front surface 1003 and/or at the front surface 1003. In aspects, as shown, the consumer electronic product 1001 can be folded in a direction 1012 to form a folded configuration that brings a first end 1027 and a second end 1037 (opposite the first end 1027) closer together (than in the unfolded configuration). Additionally, as shown, the consumer electronic product 1001 can be folded so that the front surface 1003 and/or display 1002 faces itself, although the consumer electronic product could be folded opposite the direction 1012 so that the front surface 1003 is on the outside of the consumer electronic product in the folded configuration. As discussed above with reference to FIG. 1, the consumer electronic product 1001 shown in FIG. 10 can be folded about the fold axis 102, where a central portion 1081 is located. The central portion 1081 can include the central portion 281 (e.g., of the foldable apparatus 101 and/or 301 discussed above with reference to FIGS. 2-3. As shown in FIG. 10, the central portion is positioned between a first portion 1021 including the first end 1027 and a second portion 1031 including the second end 1037. A location of the fold axis 102 can determine a first distance 1013 between the first end 1027 and the fold axis 102 (e.g., in direction 106) relative to a second distance 1015 between the second end 1037 and the fold axis 102 (e.g., in direction 1008). A total length of the consumer electronic product (e.g., length 105 in FIG. 1) can be the sum of the first distance 1013 and the second distance 1015). Also, as shown, the consumer electronic product is depicted as being in a folded or partially folded configuration with an angle A formed by front surface 1003 about the fold axis 102.

In aspects, the foldable substrate 201 comprising a glass-based substrate and/or a ceramic-based substrate can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first portion 221, the second portion 231, the central portion 281, and/or the central portion 281 can enable good impact and/or puncture resistance (e.g., resists failure for a pen drop height of about 15 centimeters (cm) or more, about 20 cm or more, about 50 cm or more). Without wishing to be bound by theory, chemically strengthening the first portion 221, the second portion 231, the central portion 281 and/or the central portion 281 can enable small (e.g., smaller than about 10 mm or less, about 5 mm or less, or about 3 mm or less) bend radii because the compressive stress from the chemical strengthening can counteract the bend-induced tensile stress on the outermost surface of the substrate. A compressive stress region may extend into a portion of the first portion and/or the second portion for a depth called the depth of compression (DOC). As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force-balanced and calibrated to the maximum central tension value provided by a SCALP measurement. As used herein, “depth of layer” (DOL) means the depth that the ions have exchanged into the substrate and/or portion (e.g., sodium, potassium). Throughout the disclosure, DOL is measured in accordance with ASTM C-1422. Without wishing to be bound by theory, a DOL is usually greater than or equal to the corresponding DOC. Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 comprising the glass-based portion and/or ceramic-based portion may comprise a first compressive stress region at the first surface area 223 that can extend to a first depth of compression from the first surface area 223. In aspects, the first portion 221 comprising a first glass-based and/or ceramic-based portion may comprise a second compressive stress region at the second surface area 225 that can extend to a second depth of compression from the second surface area 225. In aspects, the first depth of compression and/or the second depth of compression as a percentage of the substrate thickness 209 can be about 5% or more, about 10% or more, about 12% or more, about 15% or more, about 30% or less, about 25% or less, about 22% or less, about 20% or less, about 17% or less, or about 15% or less. In aspects, the first depth of compression and/or the second depth of compression as a percentage of the substrate thickness 209 can be in a range from about 5% to about 30%, from about 10% to about 25%, from about 10% to about 22%, from about 12% to about 20%, from about 12% to about 17%, from about 15% to about 17%, or any range or subrange therebetween. In aspects, the first depth of compression and/or the second depth of compression can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of compression and/or the second depth of compression can be in a range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween. By providing a first portion comprising a first glass-based and/or ceramic-based portion comprising a first depth of compression and/or a second depth of compression in a range from about 1% to about 30% of the first thickness, good impact and/or puncture resistance can be enabled.

In aspects, the first compressive stress region can comprise a maximum first compressive stress. In aspects, the second compressive stress region can comprise a maximum second compressive stress. In further aspects, the maximum first compressive stress and/or the maximum second compressive stress can be about 100 MegaPascals (MPa) or more, about 300 MPa or more, 400 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the maximum first compressive stress and/or the maximum second compressive stress can be in a range from about 100 MPa to about 1,500 MPa, from about 100 MPa to about 1,200 MPa, from about 300 MPa to about 1,200 MPa, from about 300 MPa to about 1,000 MPa, from about 400 MPa to about 1,000 MPa, from about 500 MPa to about 1,000 MPa, from about 600 MPa to about 900 MPa, from about 700 MPa to about 800 MPa, or any range or subrange therebetween. By providing a maximum first compressive stress and/or a maximum second compressive stress in a range from about 100 MPa to about 1,500 MPa, good impact and/or puncture resistance can be enabled.

In aspects, the first portion 221 can comprise a first depth of layer of one or more alkali-metal ions associated with the first compressive stress region. In aspects, the first portion 221 can comprise a second depth of layer of one or more alkali-metal ions associated with the second compressive stress region and the second depth of compression. As used herein, the one or more alkali-metal ions of a depth of layer of one or more alkali-metal ions can include sodium, potassium, rubidium, cesium, and/or francium. In aspects, the one or more alkali ions of the first depth of layer of the one or more alkali ions and/or the second depth of layer of the one or more alkali ions comprises potassium. In aspects, the first depth of layer and/or the second depth of layer as a percentage of the substrate thickness 209 can be about 5% or more, about 10% or more, about 12% or more, about 15% or more, about 30% or less, about 25% or less, about 22% or less, about 20% or less, about 17% or less, or about 15% or less. In aspects, the first depth of layer and/or the second depth of layer as a percentage of the substrate thickness 209 can be in a range from about 5% to about 30%, from about 10% to about 25%, from about 10% to about 22%, from about 12% to about 20%, from about 12% to about 17%, from about 15% to about 17%, or any range or subrange therebetween. In aspects, the first depth of layer of the one or more alkali-metal ions and/or the second depth of layer of the one or more alkali-metal ions can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of layer of the one or more alkali-metal ions and/or the second depth of layer of the one or more alkali-metal ions can be in a range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween.

In aspects, the first portion 221 may comprise a first tensile stress region. In aspects, the first tensile stress region can be positioned between the first compressive stress region and the second compressive stress region. In aspects, the first tensile stress region can comprise a maximum first tensile stress. In further aspects, the maximum first tensile stress can be about 10 MPa or more, about 20 MPa or more, about 30 MPa or more, about 100 MPa or less, about 80 MPa or less, or about 60 MPa or less. In further aspects, the maximum first tensile stress can be in a range from about 10 MPa to about 100 MPa, from about 10 MPa to about 80 MPa, from about 10 MPa to about 60 MPa, from about 20 MPa to about 100 MPa, from about 20 MPa to about 80 MPa, from about 20 MPa to about 60 MPa, from about 30 MPa to about 100 MPa, from about 30 MPa to about 80 MPa, from about 30 MPa to about 60 MPa, or any range or subrange therebetween. Providing a maximum first tensile stress in a range from about 10 MPa to about 100 MPa can enable good impact and/or puncture resistance while providing low energy fractures, as discussed below.

In aspects, the second portion 231 comprising a second glass-based and/or ceramic-based portion may comprise a third compressive stress region at the third surface area 233 that can extend to a third depth of compression from the third surface area 233. In aspects, the second portion 231 comprising a second glass-based and/or ceramic-based portion may comprise a fourth compressive stress region at the fourth surface area 235 that can extend to a fourth depth of compression from the fourth surface area 235. In aspects, the third depth of compression and/or the fourth depth of compression as a percentage of the substrate thickness 209 can be within one or more of the ranges discussed above for the first depth of compression and/or the second depth of compression. In further aspects, the third depth of compression can be substantially equal to the fourth depth of compression. In aspects, the third depth of compression and/or the fourth depth of compression can be within one or more of the ranges discussed above for the first depth of compression and/or the second depth of compression. By providing a second portion comprising a glass-based and/or ceramic-based portion comprising a third depth of compression and/or a fourth depth of compression in a range from about 1% to about 30% of the substrate thickness, good impact and/or puncture resistance can be enabled.

In aspects, the third compressive stress region can comprise a maximum third compressive stress. In aspects, the fourth compressive stress region can comprise a maximum fourth compressive stress. In further aspects, the maximum third compressive stress and/or the maximum fourth compressive stress can be within one or more of the ranges discussed above for the maximum first compressive stress and/or the maximum second compressive stress. By providing a maximum third compressive stress and/or a maximum fourth compressive stress in a range from about 100 MPa to about 1,500 MPa, good impact and/or puncture resistance can be enabled.

In aspects, the second portion 231 can comprise a third depth of layer of one or more alkali-metal ions associated with the third compressive stress region and the third depth of compression. In aspects, the second portion 231 can comprise a fourth depth of layer of one or more alkali-metal ions associated with the fourth compressive stress region and the fourth depth of compression. In aspects, the one or more alkali ions of the third depth of layer of the one or more alkali ions and/or the fourth depth of layer of the one or more alkali ions comprises potassium. In aspects, the third depth of layer and/or the fourth depth of layer as a percentage of the substrate thickness 209 can be within one or more of the ranges discussed above for the first depth of layer and/or the second depth of layer as a percentage of the substrate thickness 209. In aspects, the third depth of layer of the one or more alkali-metal ions and/or the fourth depth of layer of the one or more alkali-metal ions can be the first depth of layer and/or the second depth of layer.

In aspects, the second portion 231 may comprise a second tensile stress region. In aspects, the second tensile stress region can be positioned between the third compressive stress region and the fourth compressive stress region. In aspects, the second tensile stress region can comprise a maximum second tensile stress. In further aspects, the maximum second tensile stress can be within one or more of the ranges discussed above for the maximum first tensile stress. In aspects, the maximum first tensile stress can be substantially equal to the maximum second tensile stress. Providing a maximum second tensile stress in a range from about 10 MPa to about 100 MPa can enable good impact and/or puncture resistance while providing low energy fractures, as discussed below.

In aspects, the first depth of compression can be substantially equal to the third depth of compression. In aspects, the second depth of compression can be substantially equal to the fourth depth of compression. In aspects, the maximum first compressive stress can be substantially equal to the maximum third compressive stress. In aspects, the maximum second compressive stress can be substantially equal to the maximum fourth compressive stress. In aspects, the first depth of layer of one or more alkali-metal ions can be substantially equal to the third depth of layer of one or more alkali-metal ions. In aspects, the second depth of layer of one or more alkali-metal ions can be substantially equal to the fourth depth of layer of one or more alkali-metal ions.

In aspects, the central portion 281 can have one or more compressive stress regions. In further aspects, there can be a first central compressive stress region extending to a first central depth of compression from the first central surface area 213, and/or there can be a second central compressive stress region extending to a second central depth of compression from the second central surface area 243. In further aspects, the first central compressive stress region and/or the second central compressive stress region can be within the central portion 281 (e.g., coextensive with the first central surface area 213 and/or the second central surface area 243). In further aspects, the first central depth of compression and/or the second central depth of compression as a percentage of the central thickness 289 or the local thickness can be within one or more of the ranges discussed above for the first depth of compression and/or the second depth of compression as a percentage of the substrate thickness 209. In further aspects, the first central depth of compression and/or the second central depth of compression as a percentage of the central thickness 289 or the local thickness can be about 1% or more, about 2% or more, about 5% or more, about 8% or more, about 10% or more, about 12% or more, about 20% or less, about 17% or less, about 15% or less, about 12% or less, about 10% or less, about 7% or less, or about 5% or less. For example, the first central depth of compression and/or the second central depth of compression as a percentage of the central thickness 289 or the local thickness can be in a range from about 1% to about 20%, from about 2% to about 17%, from about 5% to about 15%, from about 7% to about 10%, or any range or subrange therebetween. In further aspects, the first central depth of compression can be substantially equal to the second central depth of compression. In further aspects, the first central depth of compression and/or the second central depth of compression can be within one or more of the ranges discussed above for the first depth of compression and/or the second depth of compression. In further aspects, the first central depth of compression and/or the second central depth of compression can be about 1 μm or more about 2 μm or more, about 4 μm or more, about 6 μm or more, about 20 μm or less, about 15 μm or less, about 10 μm or less, or about 8 μm or less. For example, the first central depth of compression and/or the second central depth of compression can be in a range from about 1 μm to about 20 μm, from about 2 μm to about 15 μm, from about 4 μm to about 10 μm, from about 6 μm to about 8 μm, or any range or subrange therebetween. By providing a central portion comprising a glass-based and/or ceramic-based portion comprising a first central depth of compression and/or a second central depth of compression in a range from about 1% to about 30% (e.g., from about 1% to about 20%) of the central thickness or local thickness, good impact and/or puncture resistance can be enabled.

In aspects, the first central compressive stress region can comprise a maximum first central compressive stress. In aspects, the second central compressive stress region can comprise a maximum second central compressive stress. In further aspects, the maximum first central compressive stress and/or the maximum second central compressive stress can be within one or more of the ranges discussed above for the maximum first compressive stress and/or the maximum second compressive stress. By providing a maximum first central compressive stress and/or a maximum second central compressive stress in a range from about 100 MPa to about 1,500 MPa, good impact and/or puncture resistance can be enabled.

In aspects, the central portion 281 can comprise a first central depth of layer of one or more alkali-metal ions associated with the first central compressive stress region and the first central depth of compression. In aspects, the central portion 281 can comprise a second central depth of layer of one or more alkali-metal ions associated with the second central compressive stress region and the second central depth of compression. In aspects, the one or more alkali ions of the first central depth of layer of the one or more alkali ions and/or the second central depth of layer of the one or more alkali ions comprises potassium. In aspects, the first central depth of layer and/or the second central depth of layer as a percentage of the central thickness 289 or the local thickness can be within one or more of the ranges discussed above for the first depth of layer and/or the second depth of layer as a percentage of the substrate thickness 209.

In aspects, the first central depth of layer and/or the second central depth of layer as a percentage of the central thickness 289 or the local thickness can be about 1% or more, about 2% or more, about 5% or more, about 8% or more, about 10% or more, about 12% or more, about 20% or less, about 17% or less, about 15% or less, about 12% or less, about 10% or less, about 7% or less, or about 5% or less. For example, the first central depth of layer and/or the second central depth of layer as a percentage of the central thickness 289 or the local thickness can be in a range from about 1% to about 20%, from about 2% to about 17%, from about 5% to about 15%, from about 7% to about 10%, or any range or subrange therebetween. In further aspects, the first central depth of layer can be substantially equal to the second central depth of layer. In further aspects, the first central depth of layer and/or the second central depth of layer can be within one or more of the ranges discussed above for the first depth of layer and/or the second depth of layer. In further aspects, the first central depth of layer and/or the second central depth of layer can be about 1 μm or more about 2 μm or more, about 4 μm or more, about 6 μm or more, about 20 μm or less, about 15 μm or less, about 10 μm or less, or about 8 μm or less. For example, the first central depth of layer and/or the second central depth of layer can be in a range from about 1 μm to about 20 μm, from about 2 μm to about 15 μm, from about 4 μm to about 10 μm, from about 6 μm to about 8 μm, or any range or subrange therebetween.

In aspects, the central portion 281 may comprise a central tensile stress region. In aspects, the central tensile stress region can be positioned between the first central compressive stress region and the second central compressive stress region. In aspects, the central tensile stress region can comprise a maximum central tensile stress. In further aspects, the maximum central tensile stress can be about 125 MPa or more, about 150 MPa or more, about 200 MPa or more, about 375 MPa or less, about 300 MPa or less, or about 250 MPa or less. In further aspects, the maximum central tensile stress can be in a range from about 125 MPa to about 375 MPa, from about 125 MPa to about 300 MPa, from about 125 MPa to about 250 MPa, from about 150 MPa to about 375 MPa, from about 150 MPa to about 300 MPa, from about 150 MPa to about 250 MPa, from about 200 MPa to about 375 MPa, from about 200 MPa to about 300 MPa, from about 200 MPa to about 250 MPa, or any range or subrange therebetween. Providing a maximum central tensile stress in a range from about 125 MPa to about 375 MPa can enable low minimum bend radii.

In aspects, one or more of the protrusions of the plurality of protrusions can be chemically strengthened with a corresponding compressive stress region extending to a corresponding depth of compression from the corresponding outer surface (e.g., upper surface). In further aspects, all of the protrusions of the plurality of protrusions can be chemically strengthened with a corresponding compressive stress region extending to a corresponding depth of compression from the corresponding outer surface (e.g., upper surface). In further aspects, the maximum compressive stress of a compressive stress region of at least one of the protrusions of the plurality of protrusions can be in one or more of the ranges discussed above for the maximum first central compressive stress and/or the maximum first central compressive stress. In even further aspects, the maximum compressive stress of a compressive stress region of at least one of the protrusions of the plurality of protrusions can be substantially equal to and/or within 100 MPa of the maximum first central compressive stress and/or the maximum first central compressive stress. In further aspects, the depth of compression of a compressive stress region of at least one of the protrusions of the plurality of protrusions can be in one or more of the ranges discussed above for the first depth of compression and/or the first central depth of compression as a percentage of the corresponding thickness and/or in absolute units. In further aspects, a depth of layer of one or more alkali metal ions (e.g., potassium) associated with the compressive stress region of at least one of the protrusions of the plurality of protrusions can be in one or more of the ranges discussed above with reference to the first depth of layer and/or the first central depth of layer. In even further aspects, a depth of layer of one or more alkali metal ions (e.g., potassium) associated with the compressive stress region of at least one of the protrusions of the plurality of protrusions can be substantially equal to the first depth of layer and/or the first central depth of layer. For example, in accordance with some of the methods discussed below involving simultaneously exposing the first major surface, the first central surface area, and the plurality of protrusions to a molten salt bath, compressive stress regions can be developed simultaneously associated depth of layer (in absolute units—μm) being substantially the same for all.

FIG. 7 schematically illustrates aspects of a foldable apparatus 301 in accordance with aspects of the disclosure in a folded configuration. As shown in FIG. 7, the foldable apparatus 301 is folded such that the first major surface 203 of the foldable substrate 201 is on the inside of the folded foldable apparatus 301. For example, a display could be located on the side of the second major surface 205, and a viewer would view the display from the side of the first major surface 203. Alternatively, a display could be located on the side of the first major surface 203, and a viewer would view the display from the side of the second major surface 205. Alternatively, although not shown, the foldable apparatus can be folded such that the second major surface 205 of the foldable substrate 201 is on the inside of the folded foldable apparatus. For example, a display could be located on the side of the second major surface 205, and a viewer would view the display from the side of the first major surface 203. Alternatively, a display could be located on the side of the first major surface 203, and a viewer would view the display from the side of the second major surface 205.

As used herein, “foldable” includes complete folding, partial folding, bending, flexing, or multiple capabilities. As used herein, the terms “fail,” “failure” and the like refer to breakage, destruction, delamination, or crack propagation. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85° C. and about 85% relative humidity.

As used herein, the “parallel plate distance” of a foldable apparatus and/or foldable substrate is measured with the following test configuration and process using a parallel plate apparatus 701 (see FIG. 7) that comprises a pair of parallel rigid stainless-steel plates 703, 705 comprising a first rigid stainless-steel plate 703 and a second rigid stainless-steel plate 705. When measuring the “parallel plate distance” for the foldable substrate 201 (e.g., the foldable apparatus 101 and/or 301 shown in FIGS. 2-3 consisting of foldable substrate 201), as shown in FIG. 7, the foldable substrate 201 is placed between the pair of plates 703 and 705 such that the second major surface 205 is in contact with the pair of plates 703 and 705. For determining a “parallel plate distance”, the distance between the parallel plates is reduced at a rate of 50 μm/second until the parallel plate distance 711 is equal to the “parallel plate distance” to be tested. Then, the parallel plates are held at the “parallel plate distance” to be tested for 24 hours at about 85° C. and about 85% relative humidity. As used herein, the “minimum parallel plate distance” is the smallest parallel plate distance that the foldable apparatus can withstand without failure under the conditions and configuration described above.

In aspects, the foldable apparatus 101 and/or 301 and/or foldable substrate 201 can achieve a parallel plate distance of 100 mm or less, 50 mm or less, 20 mm or less, 10 mm or less, 5 mm or less, 4 mm or less, 3 mm or less, 2 mm or less, or 1 mm or less. In further aspects, the foldable apparatus 101 and/or 301 and/or foldable substrate 201 can achieve a parallel plate distance of 50 millimeters (mm), or 20 mm, or 10 mm, 8 mm, 6 mm, 5 mm, 4 mm, 3 mm, 2 mm, or 1 mm. In aspects, the foldable apparatus 101 and/or 301 and/or foldable substrate 201 can comprise a minimum parallel plate distance of about 40 mm or less, about 20 mm or less, about 10 mm or less, about 8 mm or less, about 6 mm or less, about 5 mm or less, about 4 mm or less, about 3 mm or less, about 2 mm or less, about 1 mm or less, about 1 mm or more, about 2 mm or more, about 3 mm or more, about 4 mm or more, about 5 mm or more, or about 10 mm or more. In aspects, the foldable apparatus 101 and/or 301 and/or foldable substrate 201 can comprise a minimum parallel plate distance in a range from about 1 mm to about 40 mm, from about 1 mm to about 20 mm, from about 1 mm to about 10 mm, from about 1 mm to about 5 mm, from about 2 mm to about 3 mm, or any range or subrange therebetween. In aspects, the foldable apparatus 101 and/or 301 and/or foldable substrate 201 can achieve a minimum parallel plate distance in a range from about 2 mm to about 40 mm, from about 2 mm to about 20 mm, from about 2 mm to about 10 mm, from about 3 mm to about 10 mm, from about 3 mm to about 8 mm, from about 3 mm to about 6 mm, from about 4 mm to about 5 mm, or any range or subrange therebetween.

In aspects, the central width 287 of the central portion 281 of the foldable substrate 201 can be about 1.3 times or more, about 1.6 times or more, about 1.8 times or more, about 2 times or more, about 2.2 times or more, about 3 times or less, about 2.5 times or less, about 2 times or less, about 1.8 times or less, or about 1.5 times or less the minimum parallel plate distance. In aspects, the central width 287 of central portion 281 of the foldable substrate 201 as a multiple of the minimum parallel plate distance can be in a range from about 1.3 times to about 3 times, from about 1.6 times to about 2.5 times, from about 1.8 times to about 2.2 times, from about 2 times to about 2.2 times, or any range or subrange therebetween. Without wishing to be bound by theory, the length of a bend portion in an elliptical configuration between parallel plates can be about 2.2 times the parallel plate distance 711. In aspects, the central width 287 of the central portion 281 of the foldable substrate 201 can be about 1 mm or more, about 3 mm or more, about 5 mm or more, about 6 mm or more, about 8 mm or more, about 10 mm or more, about 15 mm or more, about 20 mm or more, about 100 mm or less, about 60 mm or less, about 50 mm or less, about 40 mm or less, about 35 mm or less, about 30 mm or less, about 25 mm or less, about 20 mm or less, about 15 mm or less, or about 10 mm or less. In aspects, the central width 287 of central portion 281 of the foldable substrate 201 can be in a range from about 1 mm to about 100 mm, from about 2 mm to about 60 mm, from about 3 mm to about 50 mm, from about 5 mm to about 40 mm, from about 6 mm to about 35 mm, from about 6 mm to about 30 mm, from about 8 mm to about 25 mm, from about 8 mm to about 20 mm, from about 10 mm to about 15 mm, or any range of subrange therebetween. In aspects, the central width 287 of the central portion 281 of the foldable substrate 201 can be in a range from about 2.8 mm to about 60 mm, from about 2.8 mm to about 40 mm, from about 2.8 mm to about 24 mm, from about 6 mm to about 60 mm, from about 6 mm to about 40 mm, from about 6 mm to about 24 mm, from about 9 mm to about 60 mm, from about 9 mm to about 40 mm, from about 9 mm to about 24 mm, or any range of subrange therebetween. By providing a central width within the above-noted ranges in this paragraph, folding of the foldable apparatus without failure can be facilitated.

In aspects, the central width 287 of the central portion 281 as a percentage of the length 105 of the foldable apparatus can be about 30% or more, about 35% or more, about 40% or more, about 45% or more, about 70% or less, about 60% or less, about 55% or less, or about 50% or less. In aspects, the central width 287 of the central portion 281 as a percentage of the length 105 of the foldable apparatus can range from about 30% to about 70%, from about 35% to about 60%, from about 40% to about 55%, from about 45% to about 50%, or any range or subrange therebetween. In aspects, the central width 287 of the central portion 281 can be about 30 mm or more, about 35 mm or more, about 40 mm or more, about 45 mm or more, about 50 mm or more, about 100 mm or less, about 80 mm or less, about 70 mm or less, or about 60 mm or less. In aspects, the central width 287 of the central portion 281 can range from about 30 mm to about 100 mm, from about 35 mm to about 80 mm, from about 40 mm to about 70 mm, from about 45 mm to about 60 mm, from about 50 mm to about 60 mm, or any range or subrange therebetween.

In aspects, the foldable substrate and/or the foldable apparatus can be rollable. As used herein, a foldable substrate or a foldable apparatus is “rollable” if it can achieve a threshold parallel plate distance over a length of the corresponding foldable substrate and/or foldable apparatus that is the greater of 10 mm or 10% of the length of the corresponding foldable substrate and/or foldable apparatus. For example, as shown in FIG. 37, the foldable substrate 201 is considered “rollable” when the central width 287 of the central portion 281 is greater than 10% of the length 105 (see FIG. 1) extending in the direction 106 of the length 105.

A minimum force may be used to achieve a predetermined parallel plate distance with the foldable apparatus and/or foldable substrate. The parallel plate apparatus 701 of FIGS. 7-8, described above, is used to measure the “bend force” of a foldable apparatus and/or foldable substrate in accordance of the disclosure in the Parallel Plate Test. The force to go from a flat configuration (e.g., see FIGS. 2-3) to a bent (e.g., folded) configuration (e.g., see FIGS. 7-8) comprising the predetermined parallel plate distance is measured. In aspects, an bend force comprising the minimum force to bend the foldable apparatus and/or the foldable substrate from a flat configuration to a parallel plate distance of 6 mm (e.g., when a maximum thickness of the foldable substrate is about 70 μm or more) can be about 0.24 Newtons per millimeter width of the foldable substrate (N/mm) or less, about 0.22 N/mm or less, about 0.20 N/mm or less, about 0.18 N/mm or less, about 0.01 N/mm or more, about 0.05 N/mm or more, about 0.10 N/mm or more, or about 0.15 N/mm or more. In aspects, a bend force comprising the minimum force to bend the foldable apparatus and/or the foldable substrate from a flat configuration to a parallel plate distance of 6 mm (e.g., when a maximum thickness of the foldable substrate is about 70 μm or more) can be in a range from about 0.01 N/mm to about 0.24 N/mm, from about 0.05 N/mm to about 0.22 N/mm, from about 0.10 N/mm to about 0.20 N/mm, from about 0.15 N/mm to about 0.18 N/mm, or any range or subrange therebetween. In aspects, a bend force a foldable substrate comprising a thickness profile associated with a first folding surface area in accordance with aspects of the present disclosure with a maximum thickness can be lower than a comparative bend force of a substrate with a uniform thickness equal to the maximum thickness at the same parallel plate distance (e.g., 6 mm) by 20% or more, 25% or more, or 30% or more, for example, in a range from about 20% to about 75%, from about 25% to about 50%, or from about 30% to about 40%, or any range or subrange therebetween.

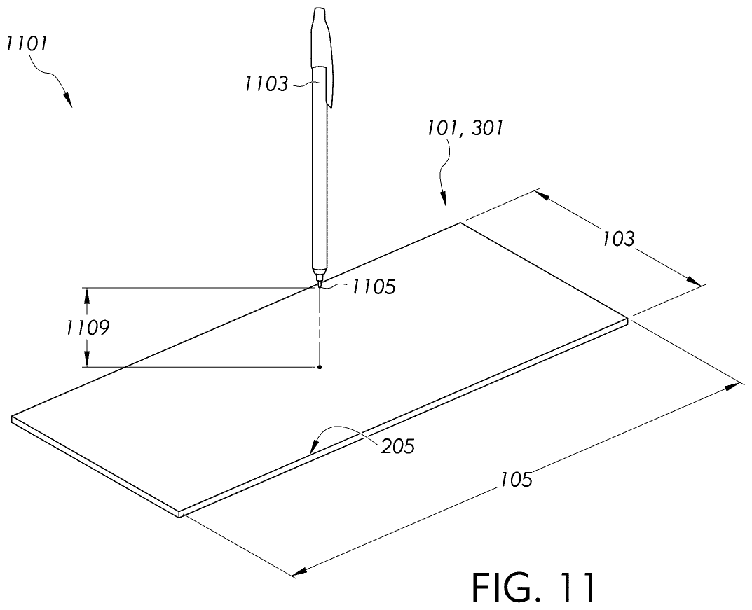

As used herein, the “Pen Drop Test” and the “Quasi-Static Puncture Test” uses a multilayer apparatus constructed using the foldable substrate to be tested. An example multilayer apparatus in FIG. 11 comprises the foldable substrate 201 with a test adhesive layer filling the central portion and further comprising a test adhesive thickness of 15 μm that is, in turn, contacting a polymer sheet comprising a thickness of 50 μm. The polymer sheet is low density polyethylene (LDPE) with a thickness of 250 μm. The test adhesive layer comprised an elastic modulus of 0.8 MPa with a tensile strength of about 0.58 MPa and an elongation at failure of about 220%. A first major surface of the second PET sheet (opposite the second major surface) forms an exterior surface of the multilayer apparatus to be tested. Unless otherwise indicated, the additional thickness 249 of the polymer-based portion 261 is 15 μm in the multilayer apparatus for the “Pen Drop Test” and the “Quasi-Static Puncture Test”.

The “Pen Drop Test” is conducted such that the polymer sheet is placed on an aluminum plate (6063 aluminum alloy, as polished to a surface roughness with 400 grit paper) with polymer sheet contacting the aluminum plate. No tape is used on the side of the sample resting on the aluminum plate. The polymer sheet faces the direction of gravity. As described herein, a load (i.e., from a pen dropped from a certain height) is imparted to an outer major surface (e.g., second major surface 205). A tube is used for the Pen Drop Test to guide a pen to an outer surface of the foldable apparatus. The tube is placed in contact with the second major surface 205 so that the longitudinal axis of the tube is substantially perpendicular to the outer major surface with the longitudinal axis of the tube extending in the direction of gravity.

Referring to FIG. 11, a pen drop apparatus 1101 includes a ballpoint pen 1103, which is a BIC Easy Glide Pen, Fine comprising a tungsten carbide ballpoint tip 1105 of 0.7 mm (0.68 mm) diameter, and a weight of 5.73 grams (g) including the cap. The ballpoint pen 1103 is held at a predetermined height 1109 from an outer surface (e.g., second major surface 205) of the multilayer apparatus being tested. A tube (not shown for clarity) is used as part of the pen drop apparatus 1101 to guide the ballpoint pen 1103 to the outer surface (e.g., second major surface 205) of the sample, and the tube is placed in contact with the second major surface 205 so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (“ABS”) shim (not shown) is employed to hold the ballpoint pen 1103 at a predetermined height 1109 for each test.

For the Pen Drop Test, the ballpoint pen 1103 is dropped with the cap attached to the top end (i.e., the end opposite the ballpoint tip 1105) so that the ballpoint tip 1105 can interact with the test sample (e.g., second major surface 205). In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. After each drop, the tube is relocated relative to the outer surface of the sample to be tested to guide the ballpoint pen 1103 to a different impact location on the outer surface of the sample to be tested. The ballpoint pen is changed to a new pen after every 5 drops, and for each new multilayer apparatus tested. In addition, all pen drops are conducted at random locations on the second major surface 205 that are at or near the center of the second major surface 205 unless indicated otherwise, with no pen drops near or on the edge of the sample. Using the Pen Drop Test, multiple samples can be tested according to the same drop sequence to generate a population with improved statistical accuracy.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or coating. A visible mechanical defect has a minimum dimension of 0.2 mm or more.

In aspects, the foldable apparatus can resist failure for a pen drop in a region comprising the first portion 221 or the second portion 231 at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 may be about 10 cm or more, about 12 cm or more, about 14 cm or more, about 16 cm or more, about 40 cm or less, or about 30 cm or less, about 20 cm or less, about 18 cm or less. In aspects, a maximum pen drop height that the foldable apparatus can withstand without failure over a region comprising the first portion 221 or the second portion 231 can be in a range from about 10 cm to about 40 cm, from about 12 cm to about 40 cm, from about 12 cm to about 30 cm, from about 14 cm to about 30 cm, from about 14 cm to about 20 cm, from about 16 cm to about 20 cm, from about 18 cm to about 20 cm, or any range or subrange therebetween.

In aspects, the foldable apparatus can resist failure for a pen drop in the central portion 281 (e.g., between the first portion 221 and the second portion 231, comprising the plurality of protrusions 251 or 351) at a pen drop height of 1 cm, 2 cm, 3 cm, 4 cm, 5 cm, or more. In aspects, a maximum pen drop height that the foldable apparatus can withstand without failure over the central portion 281 (e.g., between the first portion 221 and the second portion 231) may be about 1 cm or more, about 2 cm or more, about 3 cm or more, about 4 cm or more, about 20 cm or less, about 10 cm or less, about 8 cm or less, or about 6 cm or less. In aspects, a maximum pen drop height that the foldable apparatus can withstand without failure over the central portion 281 (e.g., between the first portion 221 and the second portion 231) can be in a range from about 1 cm to about 20 cm, from about 2 cm to about 20 cm, from about 2 cm to about 10 cm, from about 3 cm to about 10 cm, from about 3 cm to about 8 cm, from about 4 cm to about 8 cm, from about 4 cm to about 6 cm, or any range or subrange therebetween. In aspects, a maximum pen drop height that the foldable apparatus can withstand without failure of the central portion 281 (e.g., between the first portion 221 and the second portion 231) can be in a range from about 1 cm to about 10 cm, from about 1 cm to about 8 cm, from about 1 cm to about 5 cm, from about 2 cm to about 5 cm, from about 3 cm to about 5 cm, from about 4 cm to about 5 cm, or any range or subrange therebetween.

In the Quasi-Static Puncture Test, a tungsten carbide ball with a predetermined diameter is placed on the outer surface (e.g., second major surface 205) and pressed into the outer surface at a rate of 0.5 mm/min until failure. The multilayer apparatus to be tested is configured such that the polymer sheet is placed on an aluminum plate (6063 aluminum alloy, as polished to a surface roughness with 400 grit paper) with the polymer sheet. No tape is used on the side of the sample resting on the aluminum plate. Unless otherwise indicated, the predetermined diameter of the tungsten carbide ball is 0.5 mm. The foldable substrate and/or foldable apparatus can exhibit a puncture resistance as measured in a Quasi-Static Puncture Test of 2.0 kgf or more, 2.5 kgf or more, 3.0 kgf or more, 3.5 kgf or more, 4.0 kgf or more, 4.2 kgf or more, 4.4 kgf or more, 4.5 kgf or more, 4.6 kgf or more, 4.7 kgf or more, 4.8 kgf or more, 4.9 kgf or more, 5.0 kgf or more.

As used herein, a “reference substrate” refers to a substrate with a monolithic (in contrast with the foldable substrates in accordance with the present disclosure. The reference substrate comprises the same material as the foldable substrate being compared to it. The reference substrate exhibits a reference minimum parallel plate distance and a reference impact resistance. In aspects, for a reference substrate (having a monolithic thickness) with a reference minimum parallel plate distance equal to the minimum parallel plate distance of the foldable substrate (as measured in a Parallel Plate Test), an impact resistance (as measured in a Quasi-Static Puncture Test with a 0.5 mm diameter tungsten carbide ball) of the foldable substrate can be greater than the reference impact resistance (e.g., by 0.1 kgf or more, by 0.2 kgf or more, by 0.5 kgf or more, from 0.1 kgf to 2 kgf, from 0.2 kgf to 1 kgf, from 0.5 kgf to 0.8 kgf) having a reference minimum parallel plate distance equal to the minimum parallel plate distance of the foldable substrate. In aspects, a “predicted impact resistance” and a “predicted minimum parallel plate distance” can be determined from a calibration curve from a series of reference substrates with various monolithic thicknesses, where the impact resistance and minimum parallel plate distance has been measured. In further aspects, a foldable substrate with a minimum parallel plate distance (as measured in a Parallel Plate Test) can have a greater impact resistance (as measured in a Quasi-Static Puncture Test with a 0.5 mm diameter tungsten carbide ball) than a “predicted impact resistance” associated with a “predicted minimum parallel plate distance,” where the reference minimum parallel plate distance is equal to the minimum parallel plate distance of the foldable substrate. For example, as discussed below with reference to FIG. 24, area ratios have unexpectedly been identified where the impact resistance (e.g., as measured in the Quasi-Static Puncture Test) is greater than a reference sample having a monolithic thickness with the same parallel plate distance (e.g., minimum parallel plate distance) (where the parallel plate distance and impact resistance of the reference sample is either directly measured experimentally or based on a calibration curve from a plurality of reference substrates), which demonstrates that the plurality of protrusion can increase impact resistance without negatively impacting foldability (e.g., parallel plate distance). The identified area ratios with the unexpected improvement in impact resistance are discussed above, for example, from 0.10 to 0.70, from 0.20 to 0.60, or from 0.25 to 0.50.

Throughout the disclosure, a “weighted average thickness” TWA of the central portion of the foldable substrate is defined as TWA=(1−AR)*TC+AR*TP, where AR is the area ratio, TC is the central thickness, and TP is a combined protrusion thickness defined between the second central surface area of the central portion and the upper surface of a protrusion of the plurality of protrusions. For example, with reference to FIG. 2, the weight average thickness TWA is calculated based on combined protrusion thickness TP equal to the sum of the central thickness 289 and the protrusion height 259 weighted by the area ratio as a decimal (the total protrusion area divided by the total central area, as discussed above) and the central thickness 289 TC times the quantity 1 minus the area ratio as a decimal. If the central thickness TC is 50 μm, the protrusion thickness is 80 μm (combined protrusion thickness of 50 μm+80 μm=130 μm), and an area ratio of 30%, then the weight average thickness TWA=(1−0.30)*50 μm+0.30*130 μm=74 μm. In aspects, an impact resistance (as measured in a Quasi-Static Puncture Test with a 0.5 mm diameter tungsten carbide ball) of the foldable substrate can be greater than the reference impact resistance (e.g., by 0.1 kgf or more, by 0.2 kgf or more, by 0.5 kgf or more, from 0.1 kgf to 2 kgf, from 0.2 kgf to 1 kgf, from 0.5 kgf to 0.8 kgf) having a monolithic thickness equal to the weighted average thickness of the central portion of the foldable substrate. As discussed above, a “predicted impact resistance” can be determined from a calibration curve from a series of reference substrates with various monolithic thicknesses, where the impact resistance has been measured. In further aspects, a foldable substrate with a weighted average thickness of the central can have a greater impact resistance (as measured in a Quasi-Static Puncture Test with a 0.5 mm diameter tungsten carbide ball) than a “predicted impact resistance” associated with a monolithic thickness equal to the weighted average thickness of the central portion of the foldable substrate. For example, area ratios have unexpectedly been identified where the impact resistance (e.g., as measured in the Quasi-Static Puncture Test) is greater than a reference sample having a monolithic thickness equal to a weighted average thickness (defined below) (where the impact resistance of the reference sample is either directly measured experimentally or based on a calibration curve from a plurality of reference substrates), which demonstrates that the plurality of protrusion can increase impact resistance beyond what would be achieved for a substrate with the same weighted average thickness. The identified area ratios with the unexpected improvement in impact resistance are discussed above, for example, from 0.10 to 0.70, from 0.20 to 0.60, or from 0.25 to 0.50. Although not shown, the weighted average thickness can be calculated (as discussed herein) and plotted (similar to FIG. 23 but where the foldable substrates are plotted based on the weighted average thickness rather than the thickness of a monolithic substrate with a corresponding parallel plate distance), and it is contemplated that the points within the area ratios discussed herein (e.g., from 0.10 to 0.70, from 0.20 to 0.60, or from 0.25 to 0.50) will be above a calibration curve for reference samples.

In aspects, as shown in FIG. 2, the foldable apparatus 101 can further comprise a polymer-based portion 261 disposed over at least the first central surface area 213. In further aspects, as shown, the polymer-based portion 261 can be at least partially positioned in a recess 211 defined between the first central surface area 213 and the first plane 204a defined by the first major surface 203. In even further aspects, as shown, the polymer-based portion 261 can further extend beyond the recess 211 and be disposed over the first major surface 203 (e.g., first surface area 223 and/or third surface area 233) in addition to being disposed over the first central surface area 213. For example, as shown, the polymer-based portion 261 can completely cover the plurality of protrusions 251 and/or contact the entire outer surface 255a-255c of the plurality of protrusions 251, although space may be provided for an electronic device(s) and/or mechanical device(s) in the recess 211. Alternatively, although not shown, the polymer-based portion 261 can be positioned entirely within the recess 211 (e.g., not extending beyond the first plane 204a).

In further aspects, as shown in FIG. 2, the polymer-based portion can comprise a first surface area 283 and a second contact surface 285 opposite the first surface area 283. In further aspects, as shown, the second contact surface 285 can face and/or contact the first central surface area 213. In further aspects, as shown, the second contact surface 285 can contact the outer surface 255a-255c of one or more protrusions 253a-253c of the plurality of protrusions 251. In further aspects, as shown in FIG. 2, the first surface area 283 can face and/or contact the release liner 271 (e.g., fourth surface area 275) (described below) or other material (e.g., display device, another substrate).

In aspects, as shown in FIG. 2, an additional thickness 249 of the polymer-based portion 261 is defined between the first major surface 203 (e.g., first plane 204a) and the first surface area 283 of the polymer-based portion 261 as an average distance therebetween. In further aspects, as shown, the additional thickness 249 of the polymer-based portion 261 (e.g., extending beyond the recess 211—extending beyond the first plane 204a) can be about 1 μm or more, about 5 μm or more, about 10 μm or more, about 100 μm or less, about 60 μm or less, about 30 μm or less, or about 20 μm or less. In aspects, the additional thickness 249 can be in a range from about 1 μm to about 100 μm, from about 5 μm to about 100 μm, from about 5 μm to about 60 μm, from about 5 μm to about 30 μm, from about 10 μm to about 30 μm, from about 10 μm to about 20 μm, or any range or subrange therebetween. Alternatively, the region occupied by the polymer-based portion 261 in FIG. 2 may, in other aspects, be occupied by more than one polymer-based portion, for example, a stiffer polymer-based portion positioned in the recess 211 and another, less stiff optically-clear and/or pressure sensitive adhesive comprising the additional thickness 249.

In aspects, the polymer-based portion 261 can comprise an optically transparent polymer. In aspects, the polymer-based portion 261 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), polyether ether ketone (PEEK), an acrylic (e.g., polymethylmethacrylate (PMMA)), an epoxy, and/or a silicone. Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene). Examples of epoxies include bisphenol-based epoxy resins, novolac-based epoxies, cycloaliphatic-based epoxies, and glycidylamine-based epoxies. Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. In further aspects, the polymer-based portion 261 can comprise an optically clear adhesive. In even further aspects, the optically clear adhesive can comprise one or more optically transparent polymers: an acrylic (e.g., polymethylmethacrylate (PMMA)), an epoxy, silicone, and/or a polyurethane. Examples of epoxies include bisphenol-based epoxy resins, novolac-based epoxies, cycloaliphatic-based epoxies, and glycidylamine-based epoxies. In even further aspects, the optically clear adhesive can comprise, but is not limited to, acrylic adhesives, for example, 3M 8212 adhesive, or an optically transparent liquid adhesive, for example, a LOCTITE optically transparent liquid adhesive. Exemplary aspects of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel.

In aspects, the polymer-based portion 261 can comprise an elastic modulus of about 0.001 MegaPascals (MPa) or more, about 0.01 MPa or more, about 0.1 MPa or more, about 1 MPa or less, about 0.5 MPa or less, about 0.1 MPa or less, or about 0.05 MPa or less. In aspects, the polymer-based portion 261 can comprise an elastic modulus in a range from about 0.001 MPa to about 1 MPa, from about 0.01 MPa to about 1 MPa, from about 0.01 MPa to about 0.5 MPa, from about 0.05 MPa to about 0.5 MPa, from about 0.1 MPa to about 0.5 MPa, from about 0.001 MPa to about 0.5 MPa, from about 0.001 MPa to about 0.01 MPa, or any range or subrange therebetween. Alternatively, the polymer-based portion 261 can comprise an elastic modulus of about 1 MPa or more, about 10 MPa or more, about 20 MPa or more, about 100 MPa or more, about 200 MPa or more, about 1,000 MPa or more, about 5,000 MPa or less, about 3,000 MPa or less, about 1,000 MPa or less, about 500 MPa or less, or about 200 MPa or less. In aspects, the polymer-based portion 261 can comprise an elastic modulus in a range from about 1 MPa to about 5,000 MPa, from about 1 MPa to about 3,000 MPa, from about 10 MPa to about 1,000 MPa, from about 10 MPa to about 500 MPa, from about 20 MPa to about 200 MPa, from about 20 MPa to about 200 MPa, from about 100 MPa to about 200 MPa, or any range or subrange therebetween.

In aspects, as shown in FIG. 2, the foldable apparatus 101 can comprise the release liner 271 although other substrates (e.g., glass-based substrate and/or ceramic-based substrate discussed throughout the application) may be used in further aspects rather than the illustrated release liner 271. In further aspects, as shown in FIG. 2, the release liner 271, or another substrate, can be disposed over the polymer-based portion 261. In even further aspects, as shown, the release liner 271, or another substrate, can directly contact the first surface area 283 of the polymer-based portion 261. The release liner 271, or another substrate, can comprise a third surface area 273 and a fourth surface area 275 opposite the third surface area 273. As shown, the release liner 271, or another substrate, can be disposed on the polymer-based portion 261 by attaching the first surface area 283 of the polymer-based portion 261 to the fourth surface area 275 of the release liner 271, or another substrate. In aspects, as shown, the third surface area 273 of the release liner 271, or another substrate, can comprise a planar surface. In aspects, as shown, the fourth surface area 275 of the release liner 271, or another substrate, can comprise a planar surface. A substrate comprising the release liner 271 can comprise a paper and/or a polymer. Exemplary aspects of paper comprise kraft paper, machine-finished paper, poly-coated paper (e.g., polymer-coated, glassine paper, siliconized paper), or clay-coated paper. Exemplary aspects of polymers comprise polyesters (e.g., polyethylene terephthalate (PET)) and polyolefins (e.g., low-density polyethylene (LDPE), high-density polyethylene (HDPE), polypropylene (PP)). The release liner 271 can be replaced with a display device, a touch sensor, a polymer-based substrate, a glass-based substrate, and/or a ceramic-based substrate.

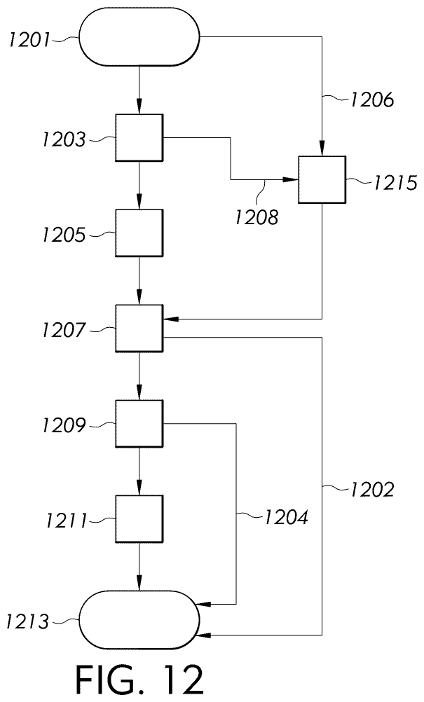

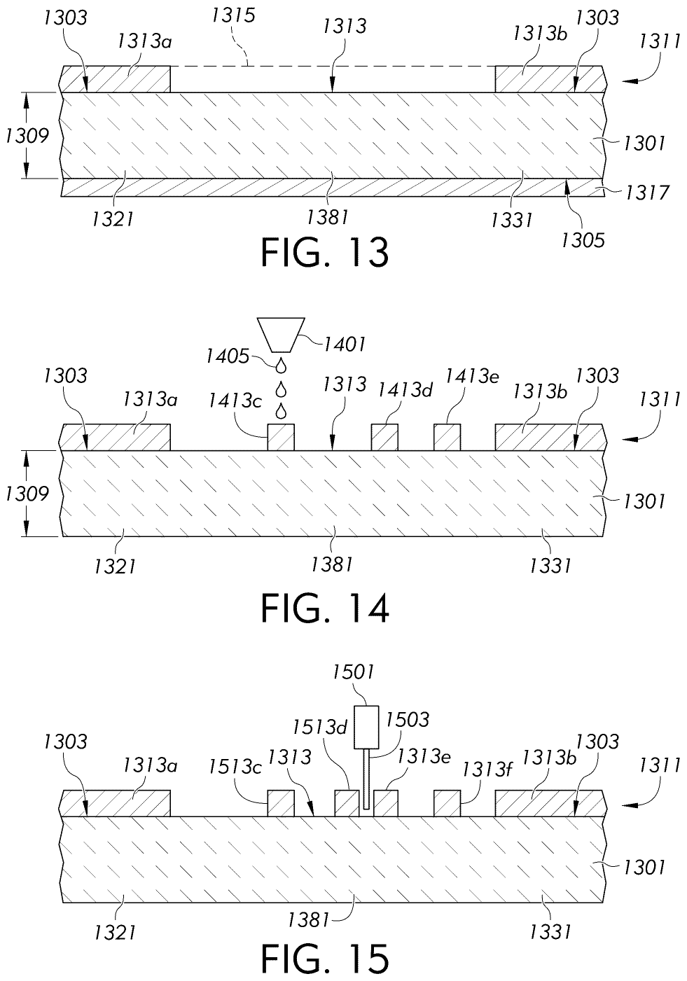

Aspects of making foldable substrates of the present disclosure will now be discussed with reference to the flow chart in FIG. 12 and exemplary steps shown in FIGS. 13-21. In aspects, the foldable apparatus 101 and/or 301 shown in FIGS. 2-7 can be formed by applying a patterned etch mask with the location and length of portions of the patterned etch mask being proportional to the width of the corresponding protrusions of the plurality of protrusions in the resulting foldable substrate to form a masked surface. Then, the masked surface can be etched (e.g., using a mineral acid, using a plasma dry etching) to form the first central surface area with associated recesses defining the plurality of protrusions.

Methods can start at step 1201 comprising providing an initial substrate (e.g., monolithic substrate), which can be provided by purchase or otherwise obtaining a substrate or by forming the foldable substrate. In aspects, the initial substrate can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals. In aspects, although not shown, at the end of step 1201, the initial substrate can comprise an initial central thickness less than the initial thickness, for example, with the initial central thickness substantially equal to the combined protrusion thickness (i.e., the sum of the resulting central thickness and the protrusion height). In further aspects, the initial central thickness can be formed by etching the central portion (e.g., uniformly) without etching the first portion and the second portion. In aspects, as shown in FIG. 13, at the end of step 1201, an etch mask 1311 having one or more portions 1313a, 1313b, and/or 1317 can be disposed over an initial first major surface 1303 in a first portion 1321, the initial first major surface 1303 in a second portion 1331, and/or an initial second major surface 1305 (e.g., opposite the initial first major surface 1303 with an initial thickness 1309 defined therebetween), although the etch mask may be deposited in subsequent steps (e.g., step 1203).

In aspects, after step 1201, methods can (follow arrow 1206) to proceed to step 1215 comprising disposing a patterned mask (e.g., etch mask 1311 have portions 1413c-1413e) on at least an initial central surface area 1313 in a central portion 1381 of the initial substrate 1301, as shown in FIG. 14. As shown, the patterned mask (e.g., etch mask 1311) includes a plurality of separate sections (e.g., portions 1413c-1413e). For example, as shown, portions 1413c-1413e of the patterned mask (e.g., etch mask 1311) can be disposed over and/or disposed on the initial central surface area 1313. These portions 1413c-1413e can be disposed using a common method with other portions of the etch mask 1311 (e.g., portions 1313a-1313b of the patterned mask in FIGS. 13-14 and/or portion 1317 shown in FIG. 13). An arrangement of the plurality of portions 1413c-1413e can correspond to an arrangement of protrusions of the plurality of protrusions to be formed (e.g., with a location of the portion corresponding to a location of the protrusion) with the understanding that the width of the protrusions will be the same or less than the width of the corresponding portions of the patterned mask, for example, depending on how the protrusions are formed (e.g., etching conditions). In aspects, as shown in FIG. 14, material 1405 for the portions 1413c-1413e can be dispensed from a container 1401 (e.g., conduit, flexible tube, micropipette, or syringe) onto the initial central surface area 1313. An exemplary aspect of forming the portions 1413c-1413e includes ink-jet deposition (e.g., ink-jet printing). For example, as shown in FIG. 14, material 1405 corresponding to an “ink” precursor of the portion 1413c-1413e can be dispensed from a container 1401 corresponding to a nozzle of an ink-jet printer head, where the material 1405 is dispensed a predetermined locations to form the portions 1413c-1413e of the patterned mask (e.g., etch mask 1311). In aspects, portions 1313a-1313b disposed over the first portion 1321 and/or the second portion 1331 can also be formed by ink-jet deposition (e.g., ink-jet printing), although the portions 1313a-1313b can be formed by other methods and/or prior to disposing the patterned mask (e.g., portions 1413c-1413e). As discussed below with reference to FIGS. 16-19, the portions of the patterned mask (e.g., etch mask) can be arranged in a row and/or a two-dimensional array, where portions in adjacent columns can be aligned of offset from one another.

Alternatively, after step 1201, methods can proceed to step 1203 comprising disposing an etch mask (e.g., portions 1313a-131b of the etch mask 1311) over the first portion 1321 and/or the second portion 1331 of the initial substrate 1301, as shown in FIG. 13. In aspects, as shown, portion 1313a can be disposed over the and/or disposed on an entirety of the initial first major surface 1303 in the first portion 1321, and/or portion 1313b can be disposed over the and/or disposed on an entirety of the initial first major surface 1303 in the second portion 1331. Similarly, portion 1317 can be disposed over and/or disposed on the initial second major surface 1305 (e.g., entirety of the initial second major surface 1305). In aspects, the portions 1313a-1313b and/or 1317 can be disposed using a doctor blade method, slot draw coating, spin-coating, or other methods known in the art.

In aspects, as shown in FIG. 13, dashed line 1315 indicates the etch mask 1311 can initially cover the initial central surface area 1313. For example, the entirety of both major surfaces of the initial substrate can be initially coated with the etch mask, which can take advantage of cost-effective deposition methods. In further aspects, the central portion of the etch mask (see region defined by dashed line 1315) can be removed, for example, if methods are to follow arrow 1208 to step 1215. Alternatively, in further aspects, the central portion of the etch mask (see region defined by dashed line 1315) can be selectively removed in subsequent processing (e.g., step 1205) to form the patterned mask in the central portion (e.g., disposed over and/or disposed on the initial central surface area 1313 as shown in FIG. 15).

In aspects, after step 1203, methods can proceed to step 1205 comprising forming a patterned mask (e.g., etch mask 1311), for example, by selectively removing portions of the etch mask in the central portion, as shown in FIG. 15. In further aspects, as shown, a laser beam 1503 can be emitted from a laser 1501, where the laser beam 1503 impinges a portion of the etch mask 1311 to divide an existing portion (e.g., portion 1313e) into new portions 1513d and 1313e and/or remove material to define a predetermined shape of portion(s) of the patterned mask (e.g., with material of the mask being removed to define the dimensions of portion 1513c). Alternatively, although not shown, the patterned mask can be formed using photolithography. For example, predetermined portions of the initial etch mask can be exposed to light and developed (e.g., exposed to a solution) to remove the predetermined portions leaving behind the patterned mask.

At the end of step 1205 or 1215, the patterned mask (e.g., etch mask 1311) can appear as shown in any of FIGS. 16-17. In aspects, as shown in FIG. 16, a portion 1313a of the etch mask 1311 can be disposed over and/or disposed on the first portion of the initial substrate, a portion 1313b of the etch mask 1311 can be disposed over and/or disposed on the second portion of the initial substrate, and the patterned mask 1603 of the etch mask 1311 disposed over and/or disposed on the central portion of the initial substrate. In further aspects, as shown, the patterned mask 1603 may not extend for the full extent of a corresponding dimension of the initial substrate, for example, excluding end portions 1605 or 1607. In even further aspects, the end portions 1605 or 1607 can be non-patterned portions of the mask or end portions 1605 or 1607 can expose corresponding portions of the initial substrate, although the patterned mask may extend over an entirety of the central portion of the initial substrate in other aspects.

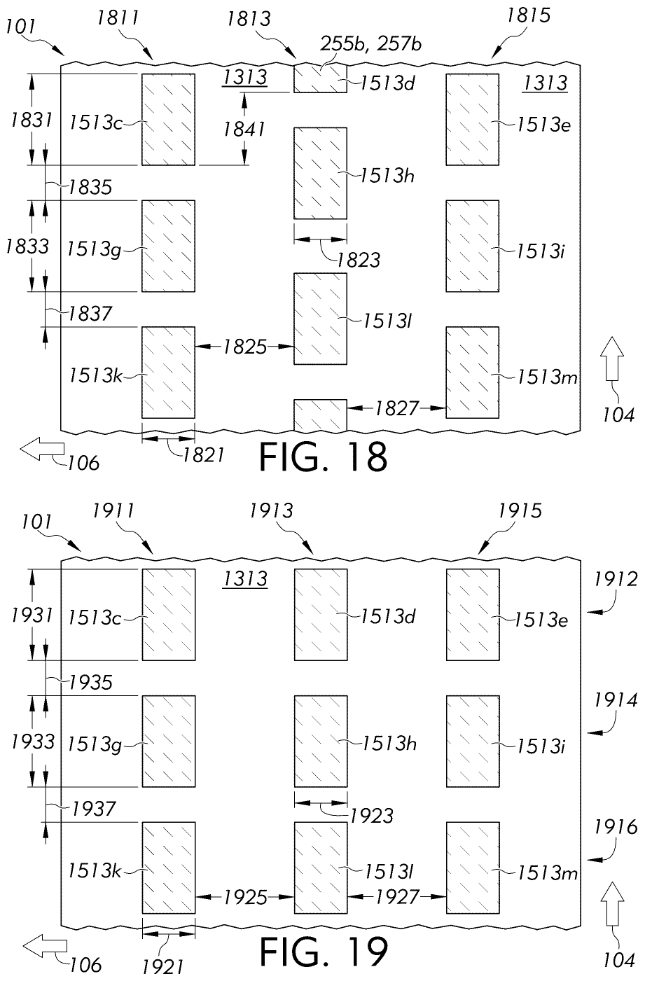

In aspects, as shown in FIGS. 16-18, the patterned mask 1603 (FIG. 16) can comprise a plurality of portions (e.g., portions 1513c-1513e in FIG. 17 and/or portions 1513c-1513e, 1513g-1513i, and/or 1513k-1513m in FIGS. 18-19) that are physically separated from one another. In aspects, as shown in FIGS. 16-17, the patterned mask can be aligned in a row extending in the direction 106. In further aspects, as shown, the plurality of protrusions can be arranged in a single row (e.g., one-dimensional row). In further aspects, a length 421 of one or more of the protrusions 253a-253c in a direction 104 (perpendicular to the direction 106), as a percentage of the width 103 of the foldable substrate 201 can be within one or more of the ranges discussed above with reference to FIG. 4 (e.g., from 50% to 100%, from 66% to 99%, from 75% to 98%, from 80% to 95%, from 85% to 92%, from 90% to 92%, or any range or subrange therebetween). As indicated by portions 1605 and 1607 in FIG. 16, the plurality of protrusions may not extend all the way to the ends (in direction 104) of the central portion, although the plurality of protrusions can extend for the entire width of the foldable substrate and/or foldable apparatus in the central portion in further aspects. As shown in FIG. 17, portions of the initial central surface area 1313 (e.g., central portion 1381 of the initial substrate) between the portions (e.g., portions 1513c and 1513d or portions 1513d and 1513e). In aspects, an initial gap 1725 or 1727 can be within one or more of the ranges discussed above for the gap width 256a of the resulting foldable substrate discussed above with reference to FIG. 4. In further aspects, the initial gap 1725 or 1727 can be substantially equal to or less than the corresponding gap width of the resulting foldable substrate. In aspects, the initial gap 1725 between a first adjacent pair of portion 1513c and 1513d can be substantially equal to the initial gap 1727 between a second adjacent pair of portions 1513d and 1513e, although the initial gap can vary based on distance from a midline (e.g., fold plane). In aspects, a width 1711 or 1713 of a portion 1513c-1513e of the patterned mask 1603 can be within one or more of the ranges discussed above for the full width 252a and/or upper width 254a a protrusion of the resulting foldable substrate discussed above with reference to FIG. 4. In further aspects, the width 1711 or 1713 can be substantially equal to or greater than the full width 252a of a protrusion in the resulting foldable substrate. In further aspects, the width 1711 or 1713 can be greater than the upper width 254a of a protrusion in the resulting foldable substrate. In aspects, the width 1711 of a first portion 1513c can be substantially equal to the width 1713 of a second portion 1513d, although the width can vary based on distance from a midline (e.g., fold plane). In aspects, a location of portions 1513c-1513e of the patterned mask 1603 can correspond to a location and/or have a width 1711 or 1713 proportional to a corresponding aspect of protrusions in the resulting foldable substrate.

In aspects, as shown in FIGS. 18-19, the portions 1513c-1513e, 1513g-1513i, and/or 1513k-1513m of the patterned mask can arranged in a two-dimensional array with rows extending in the direction 106 and columns extending in the direction 104 (perpendicular to the direction 104), where adjacent rows and/or columns can be aligned or offset. In aspects, as shown, a column 1811, 1813, 1815, 1911, 1913, or 1915 can comprise three or more portions, and/or each row can comprise at least three portions. In aspects, as shown in FIG. 19, the plurality of portions 1513c, 1513g, and 1513k in a first column 1911 can be aligned with corresponding portions 1513d, 1513h, and 1513l of a second column 1913 of the plurality of columns in the two-dimensional array (e.g., an offset 1841 in FIG. 18 of 0). For example, protrusions in a column 1912, 1914, and/or 1916 can be aligned. Alternatively, as shown in FIG. 18, the plurality of portions 1513c, 1513g, and 1513k in a first column 1811 can be offset from the plurality of portions 1513d, 1513h, and 1513l in a second column 1813 by an offset 1841 that can be within one or more of the ranges discussed above for the offset 531. In aspects, as shown in FIGS. 18-19, a portion of the patterned mask comprises a length 1831, 1833, 1931, and/or 1933 that can be within one or more of the ranges discussed above for the upper length 523 and/or 623 of the resulting foldable substrate. In further aspects, the length 1831, 1833, 1931, and/or 1933 can be greater than a corresponding upper length 523 and/or 623 due to undercutting in the etching process of step 1207. In further aspects, the length 1831, 1833, 1931, and/or 1933 can be greater than or equal to a corresponding full length 521 and/or 613 of the resulting foldable substrate. In aspects, as shown in FIGS. 18-19, an adjacent pair of portions in the same column (e.g., column 1811, 1813, 1815, 1911, 1913, or 1915) can be separated by a gap length 1835, 1837, 1935, and/or 1937 in the direction 104 that can be within one or more of the ranges discussed above for the gap width 256a, 256b, 356a, and/or 356b. As shown in FIGS. 18-19, an initial gap 1825, 1827, 1925, or 1927 can be within one or more of the ranges discussed above for the gap width 356a of the resulting foldable substrate discussed above with reference to FIGS. 5-6. In further aspects, the initial gap 1825, 1827, 1925, or 1927 can be substantially equal to or less than the corresponding gap width of the resulting foldable substrate. In aspects, a width 1821, 1823, 1921, or 1923 of a portion of the patterned mask can be within one or more of the ranges discussed above for the full width 352a and/or upper width 354a a protrusion of the resulting foldable substrate discussed above with reference to FIGS. 5-6. In further aspects, the width 1821, 1823, 1921, or 1923 can be substantially equal to or greater than the full width 352a of a protrusion in the resulting foldable substrate. In further aspects, the width 1821, 1823, 1921, or 1923 can be greater than the upper width 354a of a protrusion in the resulting foldable substrate. In aspects, the width 1821 or 1921 of a first portion 1513k can be substantially equal to the width 1823 or 1923 of a second portion 1513h, although the width can vary based on distance from a midline (e.g., fold plane). In aspects, a location of portions 1513c-1513e, 1513g-1513i, and/or 1513k-1513m of the patterned mask can correspond to a location and/or have a width 1821, 1823, 1921, or 1923 proportional to a corresponding aspect of protrusions in the resulting foldable substrate.

A mask area ratio of the patterned mask 1603 in the central portion 1381 is defined as a total area of portions of the patterned mask 1603 divided by a total surface area of the initial central surface area 1313. The mask area ratio can be within one or more of the ranges for the area ratio of the resulting foldable substrate discussed above.

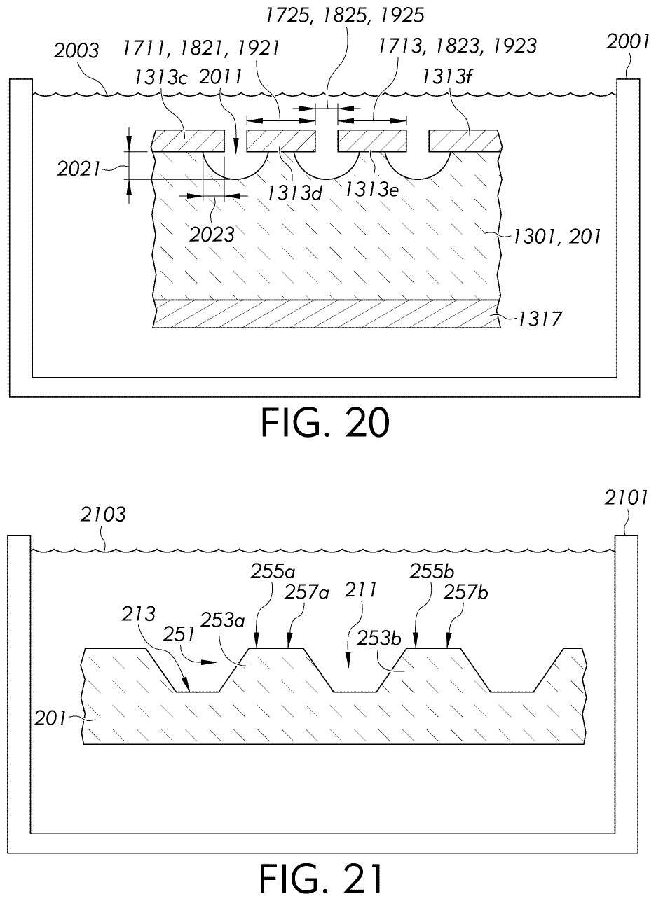

In aspects, after step 1205 or 1215, methods can proceed to step 1207 comprising etching the initial substrate to form the plurality of protrusions, as shown in FIG. 20. In aspects, as shown in FIG. 20, the etching of step 1207 can comprise contacting the initial central surface area 1313 (e.g., central portion 1381—see FIGS. 14-15) of the initial substrate 1301 with an etchant 2003 to form the foldable substrate 201. In further aspects, as shown, the etchant 2003 can be a liquid etchant contained in an etchant bath 2001. In even further aspects, the etchant can comprise one or more mineral acids (e.g., HCl, HF, H₂SO₄, HNO₃). Without wishing to be bound by theory, the polymer layer can be deflected away from the foldable substrate during etching to enable the etchant access to an additional portion of the foldable substrate that the polymer layer could otherwise be in contact with. While the etchant can contact the additional portion of the foldable substrate by deflection of the polymer layer, diffusion of the etchant to the additional portion is limited, which limits the extent of etching of the additional portion, producing the transition region.

As shown in FIG. 20, the etchant 2003 can isotropically etch the exposed portions of the initial central surface area between portions 1313c-1313f of the patterned mask to form recesses 2011 (e.g., collectively forming recess 211 in FIG. 2). Consequently, the etchant can undercut portions of the etch mask by an undercut 2023. In aspects, the undercut 2023 can be substantially equal to an etched depth 2021 (e.g., corresponding to the first distance 219 in FIG. 2). Forming the recesses 2011 defines the protrusions (with upper surfaces corresponding to where the substrate contacts the portions 1313c-1313f of the patterned mask) forming the foldable substrate 201. Also, as shown, isotropic etching can form a curved surface, the initial gap 1725, 1825, and/or 1925 relative to the undercut 2023 and/or etched depth can determine the extent to which an average slope of the sides of the protrusions appear as rounded (as in FIG. 20) or more linear and/or angular (as in FIGS. 2-3 and 21). In aspects, at the end of step 1207 methods can further comprise removing the etch mask (e.g., patterned mask).

In aspects, after step 1207, methods can proceed to step 1209 comprising chemically strengthening the foldable substrate 201, as shown in FIG. 21. In further aspects, as shown in FIG. 21, chemically strengthening the foldable substrate 201 can comprise contacting at least a portion of a foldable substrate 201 with a molten salt solution 2103 comprising potassium cations and/or sodium cations in a salt bath 2101. In further aspects, as shown in FIG. 20, step 1211 can comprise simultaneously exposing the first major surface 203, the first central surface area 213, and the plurality of protrusions 251 to the molten salt solution 2103. Chemically strengthening a foldable substrate 201 (e.g., glass-based substrate, ceramic-based substrate) by ion exchange can occur when a first cation within a depth of a surface of a foldable substrate 201 is exchanged with a second cation within a molten salt solution 2103 that has a larger radius than the first cation. For example, a lithium cation within the depth of the surface of the foldable substrate 201 can be exchanged with a sodium cation or potassium cation within the molten salt solution 2103. Consequently, the surface of the foldable substrate 201 is placed in compression and thereby chemically strengthened by the ion exchange process since the lithium cation has a smaller radius than the radius of the exchanged sodium cation or potassium cation within the molten salt solution 2103. Chemically strengthening the foldable substrate 201 can comprise contacting at least a portion of a foldable substrate 201 comprising lithium cations and/or sodium cations with sodium cations and/or potassium cations of the molten salt solution 2103. The molten salt solution 2103 can comprise potassium nitrate, potassium phosphate, potassium chloride, potassium sulfate, sodium chloride, sodium sulfate, sodium nitrate, and/or sodium phosphate, whereby lithium cations and/or sodium cations diffuse from the foldable substrate 201 to the molten salt solution 2103 contained in the salt bath 2101. In aspects, the temperature of the molten salt solution 2103 can be about 300° C. or more, about 360° C. or more, about 400° C. or more, about 500° C. or less, about 460° C. or less, or about 420° C. or less. In aspects, the temperature of the molten salt solution 2103 can be in a range from about 300° C. to about 500° C., from about 360° C. to about 500° C., from about 400° C. to about 500° C., from about 300° C. to about 460° C., from about 360° C. to about 460° C., from about 400° C. to about 460° C., from about 400° C. to about 420° C., from about 300° C. to about 400° C., from about 360° C. to about 420° C., or any range or subrange therebetween. In aspects, the foldable substrate 201 can be in contact with the molten salt solution 2103 for about 5 minutes or more, about 10 minutes or more, about 20 minutes or more, about 30 minutes or more, about 1 hour or more, about 3 hours or more, about 8 hours or less, about 4 hours or less, about 2 hours or less, about 1 hour or less, about 45 minutes or less, or about 20 minutes or less. In aspects, the foldable substrate 201 can be in contact with the molten salt solution 2103 for a time in a range from about 5 minutes to about 8 hours, from about 10 minutes to about 4 hours, from about 20 minutes to about 2 hours, from about 30 minutes to about 1 hour, or any range or subrange therebetween. At the end of step 1211, the foldable substrate 201 can comprise the compressive stress regions discussed above (e.g., first compressive stress region extending to a first depth of compression from the first major surface in the first portion, second compressive stress region extending to a second depth of compression from the first major surface in the second portion, and/or first central compressive stress region extending to the first central depth of compression from the first central surface area).

After step 1207 and/or 1209, methods can proceed to step 1211 comprising assembling a foldable apparatus (e.g., and/or consumer electronic product) using the foldable substrate. For example, a precursor solution can be disposed over the first central surface area (e.g., in the recess) and cured to form a polymer-based portion (e.g., polymer-based portion 261 shown in FIG. 2). Also, a release liner 271 (see FIG. 2), display device, or other components can be disposed thereon. Additionally and/or alternatively, a coating (e.g., hard-coating, anti-fingerprint coating) can be disposed on the second major surface 205.

After step 1207, 1209, or 1211, methods can proceed to step 1213, where methods of making the foldable substrate and/or foldable article can be complete. In aspects, methods of making the foldable substrate in accordance with aspects of the disclosure can proceed along steps 1201, 1203, 1205, 1207, 1209, 1211, and 1213 of the flow chart in FIG. 12, sequentially as discussed above. In aspects, methods can follow arrow 1206 from step 1201 to step 1215, for example, if the patterned mask is to be formed by disposing material (e.g., ink-jet printing). In aspects, methods can follow arrow 1208 from step 1203 to step 1215, for example, if the patterned mask in the central portion is to be formed by disposing material (e.g., ink-jet printing) after portions of a mask are formed over the first portion and/or the second portion of the initial substrate. In aspects, methods can follow arrow 1202 from step 1207 to step 1213, for example, if methods of making the foldable substrate and/or foldable apparatus are complete at the end of step 1213. In aspects, methods can follow arrow 1204 from step 1209 to step 1213, for example, if methods of making the foldable substrate and/or foldable apparatus are complete at the end of step 1213. Any of the above options may be combined to make a foldable apparatus in accordance with the embodiments of the disclosure.

### EXAMPLES

Various aspects will be further clarified by the following examples. Examples comprised glass-based substrates (Composition 1 having a nominal composition in mol % of: 63.6 SiO₂; 15.7 Al₂O₃; 10.8 Na₂O; 6.2 Li₂O; 1.16 ZnO; 0.04 SnO₂; and 2.5 P₂O₅) with dimensions of 100 mm by 160 mm in a direction perpendicular to the substrate thickness. Unless otherwise indicated, the example foldable substrates discussed in this section had a substrate thickness of 130 μm and a central thickness of 80 μm with protrusions extending from the first central surface area for 50 μm (such that the upper surface of the protrusion was coplanar with the first major surface). Reference substrates comprised a monolithic thickness (no recesses or protrusions) with various thicknesses. Parallel plate distances were measured in accordance with the Parallel Plate Test described above, and the impact resistance was measured using the Quasi-Static Puncture Test with a 0.5 mm diameter tungsten carbide ball incident on the central surface area of the substrate (flush with the second major surface).

Tables 1-2 present properties of the patterned mask and resulting plurality of protrusions in example foldable substrates experimentally fabricated in accordance with aspects of the present disclosure. Table 1 presents the properties for “block” designs (see FIG. 4) while Table 2 presents the properties of “kerf” designs (see FIG. 5). For simplicity and to isolate the effect of the plurality of the protrusions, all foldable substrates and reference substrates discussed in this section were not chemically strengthened.

TABLE 1
Properties of Examples 1-16 with the Block Design

| Example | 1 | 2 | 3 | 4 | 5 | 6 | 8 | 9 | 10 |
|---|---|---|---|---|---|---|---|---|---|
| Mask Width (mm) | 2.0 | 1.0 | 0.6 | 0.45 | 0.4 | 0.4 | 0.4 | 0.4 | 0.4 |
| Mask Gap (μm) | 60 | 60 | 60 | 60 | 150 | 350 | 600 | 1200 | 2200 |
| Protrusion Width | 1860 | 860 | 460 | 310 | 260 | 260 | 260 | 260 | 260 |
| (μm) | | | | | | | | | |
| Gap Width (μm) | 200 | 200 | 200 | 200 | 290 | 490 | 740 | 1340 | 2340 |
| Area % | 83% | 75% | 64% | 56% | 44% | 32% | 24% | 15% | 9% |

| Example | 11 | 12 | 13 | 14 | 15 | 16 |
|---|---|---|---|---|---|---|
| Mask Width (mm) | 0.30 | 0.22 | 0.22 | 0.22 | 0.22 | 0.22 |
| Mask Gap (row) (μm) | 60 | 60 | 60 | 200 | 500 | 800 |
| Protrusion Width (μm) | 160 | 80 | 80 | 80 | 80 | 80 |
| Gap Width (μm) | 200 | 200 | 200 | 340 | 640 | 940 |
| Area % | 52% | 41% | 26% | 18% | 10% | 7% |

TABLE 2
Properties of Examples 16-31 with the Kerf Design (Length 4.75 μm)

| Example | 17 | 18 | 19 | 20 | 21 | 22 | 23 | 24 | 25 |
|---|---|---|---|---|---|---|---|---|---|
| Mask Width (mm) | 2.0 | 1.0 | 0.6 | 0.45 | 0.4 | 0.4 | 0.4 | 0.4 | 0.4 |
| Mask Gap | 60 | 60 | 60 | 60 | 150 | 350 | 600 | 1200 | 2200 |
| (row) (μm) | | | | | | | | | |
| Mask Gap | 250 | 250 | 250 | 250 | 250 | 250 | 250 | 250 | 250 |
| (column) (μm) | | | | | | | | | |
| Protrusion Width | 1860 | 860 | 460 | 310 | 260 | 260 | 260 | 260 | 260 |
| (μm) | | | | | | | | | |
| Gap Width | 200 | 200 | 200 | 200 | 290 | 490 | 740 | 1340 | 2340 |
| (row) (μm) | | | | | | | | | |
| Minimum distance | 390 | 390 | 390 | 390 | 390 | 390 | 390 | 390 | 390 |
| (column) (μm) | | | | | | | | | |
| Area % | 90% | 81% | 70% | 61% | 47% | 35% | 26% | 16% | 10% |

| Example | 26 | 27 | 28 | 29 | 30 | 31 |
|---|---|---|---|---|---|---|
| Mask Width (mm) | 0.4 | 0.3 | 0.22 | 0.22 | 0.22 | 0.22 |
| Mask Gap | 60 | 60 | 60 | 200 | 500 | 800 |
| (row) (μm) | | | | | | |
| Mask Gap | 250 | 250 | 250 | 250 | 250 | 250 |
| (column) (μm) | | | | | | |
| Protrusion Width | 260 | 160 | 80 | 80 | 80 | 80 |
| (μm) | | | | | | |
| Gap Width | 200 | 200 | 200 | 340 | 640 | 940 |
| (row) (μm) | | | | | | |
| Minimum distance | 390 | 390 | 390 | 390 | 390 | 390 |
| (column) (μm) | | | | | | |
| Area % | 57% | 44% | 29% | 19% | 11% | 8% |

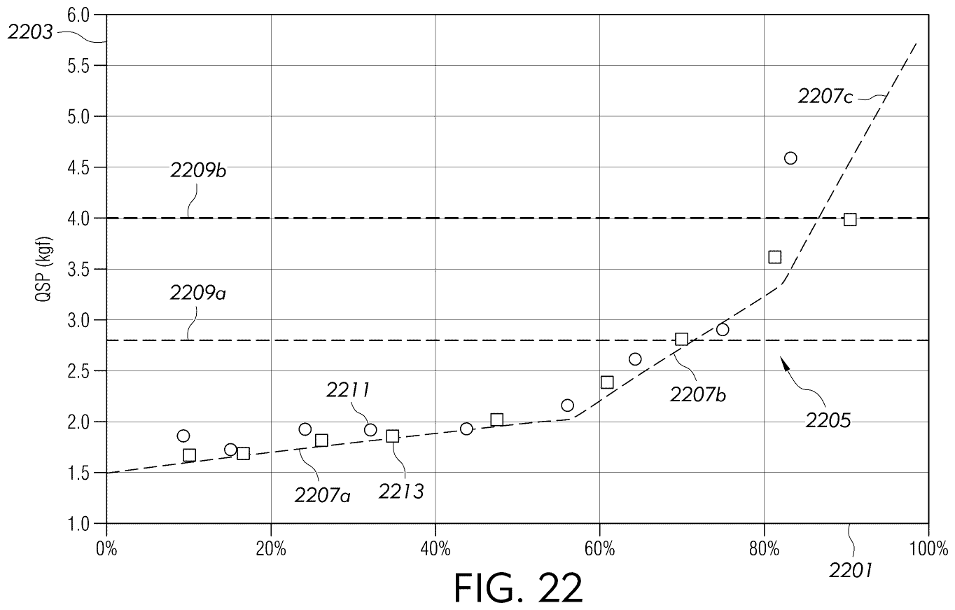

In FIGS. 22-24, circle-shaped points (e.g., points 2211, 2313, 2315, 2321, 2413, 2415, 2417, and 2421) correspond to foldable substrates with protrusions arranged in a row extending for substantially the corresponding dimension of the foldable substrate (corresponding to the foldable substrate shown in FIG. 4) referred to as “blocks” herein. In FIGS. 22-24, the square-shaped points (e.g., points 2213, 2317, 2323, 2419, and 2423) correspond to foldable substrates with protrusions arranged in a two-dimensional array with adjacent columns offset from one another (corresponding to the foldable substrate in FIG. 5) referred to as “kerfs” herein. In FIGS. 23-24, triangle shapes (e.g., points 2305 and 2405) correspond to reference substrates. For

FIG. 22 presents impact resistance as measured by the Quasi-Static Puncture Test in kilograms force (kgf) on the vertical axis 2203 (i.e., y-axis) as a function of an area ratio in percent (%) on the horizontal axis 2201 (i.e., x-axis). In FIG. 22, dashed line 2209a corresponds to the impact resistance (2.8 kgf) of a reference substrate with a monolithic thickness of 100 μm, and line 2209b corresponds to the impact resistance (4.0 kgf) of a reference substrate having a monolithic thickness of 120 μm. As shown in FIG. 22, all of the points 2205 shown for the example foldable substrates, including foldable substrates having the block design of protrusions (point 2211) and the kerf design of protrusions (point 2213), roughly follow the multi-segmented trendline 2207a-2207c. The first segment of the trendline 2207a (for an area ratio less than about 55%) has a lower slope than the other segments of the multi-segmented trendline 2207a-2207c. The middle segment 2207b extends between area ratios of about 55% to about 85% and has a steeper slope than the first segment 2207a. Based on the presentation of data in FIG. 22, it would appear that protrusions associated with an area ratio from greater than 55% to about 85% has improved impact resistance per increase in area ratio. However, the second segment of the trendline 2207b appears to intersect line 2209a at an area ratio of about 70%, but the weighted average thickness for an area ratio of 70% is 106 μm, which is greater than the 100 μm thickness of the reference sample corresponding to line 2209a. Consequently, it would appear that foldable substrates with the plurality of protrusions do not provide benefits relative to a reference substrate with the same weighted average thickness (since a larger weighted average thickness of 106 μm has the same impact resistance of a 100 μm reference sample) in the region suggested by the multi-segmented trendline 2207a-2207c. Based on these results, it is unlikely that a person having ordinary skill in the art would further investigate the designs using a plurality of protrusions in accordance with the present disclosure. However, as discussed in the following paragraphs with reference to FIGS. 23-24, the inventors of the present disclosure have unexpectedly discovered improved impact resistance relative to comparative reference substrates.

FIG. 23 presents impact resistance as measured by the Quasi-Static Puncture Test in kilograms force (kgf) on the vertical axis 2303 (i.e., y-axis) as a function of monolithic thickness (μm) of the reference samples on the horizontal axis 2301 (i.e., x-axis). For points 2313, 2315, 2317, 2321, and 2323 (e.g., clusters 2309 and 2311), the position along the horizontal axis 2301 (i.e., x-axis) for the sample was determined based on a reference sample (or the calibration curve) with the same minimum parallel plate distance as the sample. As shown in FIG. 23, calibration curve 2307 shows the trend of points 2305 corresponding to reference substrates with monolithic thicknesses from 40 μm to 140 μm. Cluster 2311 of points 2321 and 2323 correspond to area ratios greater than 80%, and cluster 2311 is below the calibration curve, indicating that there is no improvement in impact resistance relative to corresponding monolithic substrates. However, cluster 2309 of points 2313, 2315, and 2317 for area ratios from 10% to 70% (e.g., from 20% to 60%, or from 25% to 50%) are above the calibration curve 2307. Being above the calibration curve corresponds to an improvement in impact resistance beyond what would be expected (or obtained) for a monolithic substrate having a minimum parallel plate distance equal to that of the foldable substrate. Especially in view of the trend observed in FIG. 22, the improved impact resistance for cluster 2309 (being above calibration curve 2307) is an unexpected benefit from providing the foldable substrate with the plurality of protrusions.

FIG. 24 presents impact resistance as measured by the Quasi-Static Puncture Test in kilograms force (kgf) on the vertical axis 2403 (i.e., y-axis) as a function of parallel plate distance in millimeters (mm) on the horizontal axis 2401 (i.e., x-axis). As shown in FIG. 24, calibration curve 2407 shows the trend of points 2405 corresponding to reference substrates with monolithic thicknesses having minimum parallel plate distances from about 4 mm to about 19 mm. Cluster 2411 of points 2421 and 2423 correspond to area ratios greater than 80%, and cluster 2411 is at or below the calibration curve, indicating that there is no improvement in impact resistance relative to monolithic substrates with a minimum parallel plate distance equal to that of the foldable substrate. However, cluster 2409 of points 2413, 2415, and 2417 for area ratios from 10% to 70% (e.g., from 20% to 60%, or from 25% to 50%) are above the calibration curve 2407. Being above the calibration curve corresponds to an improvement in impact resistance beyond what would be expected (or obtained) for a monolithic substrate with a minimum parallel plate distance equal to that of the foldable substrate. Especially in view of the trend observed in FIG. 22, the improved impact resistance for cluster 2409 (being above calibration curve 2407) is an unexpected benefit from providing the foldable substrate with the plurality of protrusions.

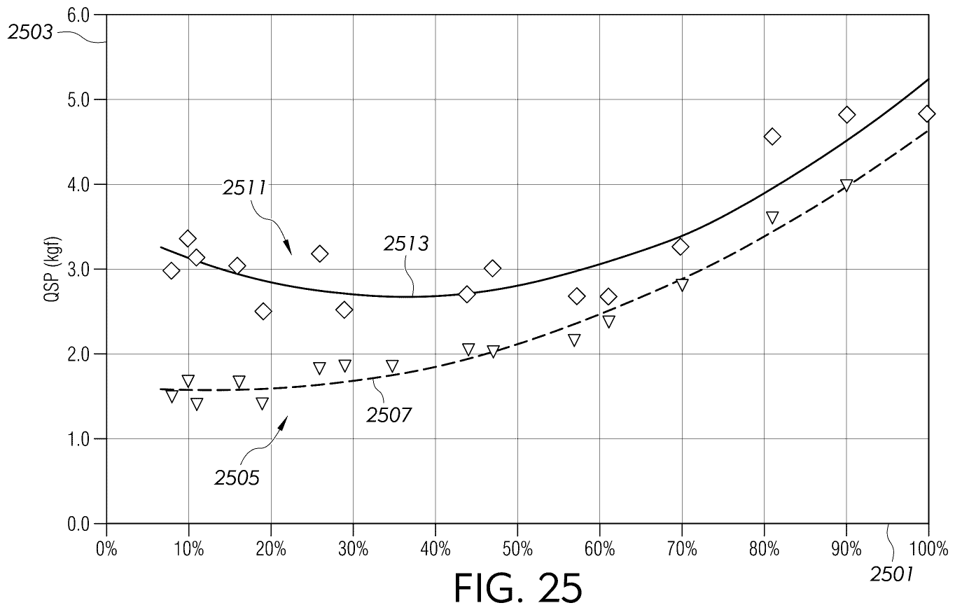

FIG. 25 presents impact resistance as measured by the Quasi-Static Puncture Test in kilograms force (kgf) on the vertical axis 2503 (i.e., y-axis) as a function of area ratio in percent (%) on the horizontal axis 2501 (i.e., x-axis). Additional foldable substrates were fabricated for FIG. 25 (beyond those shown in FIGS. 23-24) to further investigate the behavior of the block design and the kerf design within the range of unexpected benefits found from FIGS. 23-24 and to evaluate the effect of the central thickness of the impact resistance in these designs. Points 2505 correspond to foldable substrates with a central thickness of 80 μm (with the protrusions extending for 70 μm) while points 2511 correspond to foldable substrates with a central thickness of 120 μm (with the protrusions extending for 30 μm). Curve 2507 shows the trend of points 2505, and curve 2513 shows the trend of points 2511. As shown in FIG. 25, points 2505 and curve 2507 show that the impact resistance increases with increasing area ratio (e.g., monotonically. However, the trend for increasing areas ratio (of area ratio less than 50%, 40%, and/or 30%) of points 2511 and curve 2513 (central thickness of 120 μm rather than 80 μm) appears to to be relatively flat or even downwardly inclined for relatively low area ratio. This suggests that larger central thickness (e.g., as a percentage of the substrate thickness) may further have unexpected benefits for low area ratio (e.g., from about 10% to about 50%, from 10% to 40%, from 10% to 30%, or from 10% to 20%).

The above observations can be combined to provide foldable substrate and/or foldable apparatus comprising foldable substrates, foldable substrates, and methods of making foldable apparatus and foldable substrates comprising foldable substrates that comprise a first portion, a second portion, and a central portion positioned therebetween. The foldable substrate can comprise glass-based and/or ceramic-based portions, which can provide good dimensional stability, reduced incidence of mechanical instabilities, good impact resistance, and/or good puncture resistance. The portions can comprise one or more compressive stress regions, which can further provide increased impact resistance and/or increased puncture resistance. By providing a foldable substrate comprising a glass-based and/or ceramic-based substrate, the foldable substrate can also provide increased impact resistance and/or puncture resistance while simultaneously facilitating good folding performance. In aspects, the substrate thickness can be sufficiently large (e.g., from about 50 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters (mm) or less, about 5 mm or less, or about 3 mm or less) based on the reduced thickness in the central portion, which can enable the foldability and/or rollability of the foldable substrate and/or foldable apparatus.

In aspects, the foldable apparatus and/or foldable substrates can comprise a recess, for example, a first central surface area recessed from a first major surface by a first distance. Providing a recess can form a central thickness that is less than a substrate thickness, which can facilitate folding of the foldable substrate and/or foldable apparatus. Further, providing the recess (e.g., with the plurality of protrusions) on only one side of the foldable substrate can provide a uniform opposite surface that can present a smooth, consistent surface for a user to interact with.

The inventors of the present application have unexpectedly determined that providing a plurality of protrusions can improve impact resistance (e.g., as measured in the Quasi-Static Puncture Test) while allowing the foldable substrate and/or foldable substrate to still attain low parallel plate distances. Specifically, as discussed below with reference to FIG. 24, area ratios have unexpectedly been identified where the impact resistance (e.g., as measured in the Quasi-Static Puncture Test) is greater than a reference sample having a monolithic thickness with the same parallel plate distance (e.g., minimum parallel plate distance) (where the parallel plate distance and impact resistance of the reference sample is either directly measured experimentally or based on a calibration curve from a plurality of reference substrates), which demonstrates that the plurality of protrusion can increase impact resistance without negatively impacting foldability (e.g., parallel plate distance). Also, area ratios have unexpectedly been identified where the impact resistance (e.g., as measured in the Quasi-Static Puncture Test) is greater than a reference sample having a monolithic thickness equal to a weighted average thickness (defined below) (where the impact resistance of the reference sample is either directly measured experimentally or based on a calibration curve from a plurality of reference substrates), which demonstrates that the plurality of protrusion can increase impact resistance beyond what would be achieved for a substrate with the same weighted average thickness. Being above the calibration curve corresponds to an improvement in impact resistance beyond what would be expected (or obtained) for a monolithic substrate with a minimum parallel plate distance equal to that of the foldable substrate. For example, providing an area ratio from 0.10 to 0.70 (e.g., from 0.20 to 0.60, or from 0.25 to 0.50) can unexpectedly provide improved impact resistance (e.g., as measured in the Quasi-Static Puncture Test), for example, relative to a reference substrate with the same parallel plate distance or with the same weighted average thickness. Also, providing a plurality of protrusions arranged such that there is not a protrusion of the plurality of protrusions impinged by the midline (e.g., fold plane 109) can decrease a bend-induced stress on the foldable substrate.

Providing rounded corners for the cross-sectional shape of a protrusion of the plurality of protrusions can decrease stress concentrations at the corners of the protrusions, which can decrease a maximum bending stress associated with folding to a predetermined parallel plate distance and/or increase a reliability of folding the foldable substrate and/or foldable apparatus. Also, providing a plurality of protrusions (e.g., comprising substantially the substrate thickness) can increase a puncture resistance of the central region (e.g., due to the increased thickness of the plurality of protrusions relative to the first central surface area) while the central region (excluding the plurality of protrusions) can still facilitate folding of the foldable apparatus and/or foldable substrate. In further aspects, providing a plurality of substantially constant local thicknesses (e.g., substantially equal to the central thickness) between corresponding adjacent pairs of protrusions of the plurality of protrusions can simplify manufacturing, for example, enabling the local thickness between an adjacent pair of protrusions to be formed in a single etching step (e.g., with the portions corresponding to the adjacent pair of protrusions being masked).

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

What is claimed:

1. A foldable substrate comprising:
a substrate thickness defined between a first major surface and a second major surface opposite the first major surface in a thickness direction;
a first portion comprising the substrate thickness;
a second portion comprising the substrate thickness;
a central portion positioned between the first portion and the second portion, the central portion comprising a first central surface area and a second central surface area opposite the first central surface area, a central thickness defined between the first central surface area and the second central surface area in the thickness direction the central thickness is less than the substrate thickness; and
a plurality of protrusions extending from the first central surface area by at least 5 micrometers, each protrusion comprising an upper surface within 5 micrometers in the thickness direction from a point corresponding to a maximum height of the corresponding protrusion from the first central surface area;
a total protrusion area is a sum of an area of the upper surface of each protrusion of the plurality of protrusions, a total central area is an area of the central portion in a plane perpendicular to the thickness direction and impinging the first central surface area,
wherein the foldable substrate comprises a glass-based material or a ceramic-based material, and an area ratio of the total protrusion area to the total central area is from 0.10 to 0.70.

2. The foldable substrate of claim 1, wherein the area ratio of the total protrusion area to the total central area is from 0.20 to 0.60.

3. The foldable substrate of claim 1, wherein the foldable substrate achieves at least one of:
a minimum parallel plate distance in a Parallel Plate Test from 1 millimeter to 6 millimeters; or
a parallel plate distance in a Parallel Plate Test of 5 millimeters or less.

4. The foldable substrate of claim 1, wherein the foldable substrate achieves a minimum parallel plate distance in a Parallel Plate Test, a reference substrate comprises a monolithic thickness and achieves a reference minimum parallel plate distance in the Parallel Plate Test substantially equal to the minimum parallel plate distance of the foldable substrate, and a puncture resistance of the foldable substrate measured in a Quasi-Static Puncture Test is greater than a reference puncture resistance of the reference substrate measured in the Quasi-Static Puncture Test.

5. The foldable substrate of claim 1, wherein the foldable substrate exhibits a puncture resistance measured in a Quasi-Static Puncture Test, a weighted average thickness TWA of the central portion defined as TWA=(1−AR)*TC+AR*TP, wherein AR is the area ratio, TC is the central thickness, and TP is a combined protrusion thickness defined between the second central surface area of the central portion and the upper surface of a protrusion of the plurality of protrusions, and the puncture resistance is greater than a reference puncture resistance of a reference substrate comprising a uniform thickness equal to the weighted average thickness and the same material as the foldable substrate.

6. The foldable substrate of claim 1, wherein the first major surface extends along a first plane, a first distance is defined between the first plane and the first central surface area in the thickness direction, a protrusion height defined between the first central surface area and the upper surface of a protrusion of the plurality of protrusions in the thickness direction, and the first distance is greater than or equal to the protrusion height.

7. The foldable substrate of claim 1, wherein a width of the upper surface of a protrusion of the plurality of protrusions in a direction between the first portion and the second portion is from 20 micrometers to 1 millimeter.

8. The foldable substrate of claim 1, wherein the plurality of protrusions are aligned in a row extending in a first direction between the first portion and the second portion.

9. The foldable substrate of claim 8, wherein the plurality of protrusions are arranged in a two-dimensional array including the row extending between the first portion and the second portion, at least three protrusions of the plurality of protrusions in a column of a plurality of columns extending perpendicular to the row, and the protrusions of the plurality of protrusions in a first column of the plurality of columns is offset from corresponding protrusions of a second column of the plurality of columns, where the first column is adjacent to the second column.

10. The foldable substrate of claim 9, wherein a gap width between adjacent protrusions in the row in the first direction is from 150 micrometers to 1 millimeter.

11. The foldable substrate of claim 1, wherein the second major surface is flush with the second central surface area.

12. The foldable substrate of claim 1, further comprising:
a first compressive stress region extending to a first depth of compression from the first major surface in the first portion;
a second compressive stress region extending to a second depth of compression from the second major surface in the first portion;
a third compressive stress region extending to a third depth of compression from the first major surface in the second portion;
a fourth compressive stress region extending to a fourth depth of compression from the second major surface in the second portion;
a first central compressive stress region extending to a first central depth of compression from the first central surface area; and
a second central compressive stress region extending to a second central depth of compression from the second central surface area.

13. A consumer electronic product, comprising:
a housing comprising a front surface, a back surface, and a side surface;
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the foldable substrate of claim 1.

14. A method of making a foldable substrate comprising:
disposing a patterned mask on a central portion of an initial major surface of an initial substrate, the patterned mask comprising a plurality of separate sections; and
etching the initial major surface of the initial substrate to form a central portion of the foldable substrate with a plurality of protrusions extending from a first central surface area by at least 5 micrometers, and the plurality of protrusions corresponding to the plurality of separate sections of the patterned mask on central portion of the initial major surface,
wherein each protrusion of the plurality of protrusions comprising an upper surface within 5 micrometers in the thickness direction from a point corresponding to a maximum height of the corresponding protrusion from the first central surface area,
a total protrusion area is a sum of sum of an area of the upper surface of each protrusion of the plurality of protrusions, a total central area is an area of the central portion in the plane perpendicular to the thickness direction and impinging the first central surface area, the foldable substrate comprises a glass-based material or a ceramic-based material, and an area ratio of the total protrusion area to the total central area is from 0.10 to 0.70.

15. The method of claim 14, wherein the disposing the patterned mask comprises ink-jet printing the patterned mask.

16. The method of claim 14, wherein the plurality of sections are aligned in a row extending in a first direction, the plurality of sections are arranged in a two-dimensional array including the row, at least three sections of the plurality of sections are in a column of a plurality of columns extending perpendicular to the row, and sections of the plurality of sections in a first column of the plurality of columns is offset from corresponding section of a second column of the plurality of columns, where the first column is adjacent to the second column.

17. The method of claim 14, wherein the foldable substrate comprises:
a substrate thickness defined between the first major surface and a second major surface opposite the first major surface in a thickness direction;
a first portion comprising the substrate thickness;
a second portion comprising the substrate thickness; and
a central portion positioned between the first portion and the second portion, the central portion comprising the first central surface area and a second central surface area opposite the first central surface area, a central thickness defined between the first central surface area and the second central surface area in the thickness direction the central thickness is less than the substrate thickness.

18. The method of claim 17, wherein the foldable substrate achieves a minimum parallel plate distance in a Parallel Plate Test, a reference substrate comprises a monolithic thickness and achieves a reference minimum parallel plate distance in the Parallel Plate Test substantially equal to the minimum parallel plate distance of the foldable substrate, and a puncture resistance of the foldable substrate measured in a Quasi-Static Puncture Test is greater than a reference puncture resistance of the reference substrate measured in the Quasi-Static Puncture Test.

19. The method of claim 17, wherein the foldable substrate exhibits a puncture resistance measured in a Quasi-Static Puncture Test, a weighted average thickness TWA of the central portion defined as TWA=(1−AR)*TC+AR*TP, wherein AR is the area ratio, TC is the central thickness, and TP is a combined protrusion thickness defined between the second central surface area of the central portion and the upper surface of a protrusion of the plurality of protrusions, and the puncture resistance is greater than a reference puncture resistance of a reference substrate comprising a uniform thickness equal to the weighted average thickness and the same material as the foldable substrate.

20. The method of claim 14, further comprising chemically strengthening the foldable substrate by simultaneously exposing the first major surface, the first central surface area, and the plurality of protrusions to a molten salt solution,
wherein the chemically strengthening forms:
a first compressive stress region extending to a first depth of compression from the first major surface in the first portion;
a second compressive stress region extending to a second depth of compression from the first major surface in the second portion; and
a first central compressive stress region extending to a first central depth of compression from the first central surface area.
